(19) United States
(12) Patent Application Publication
(10) Pub. No.: US 2012/0064651 A1
(43) Pub. Date: Mar. 15, 2012

(54) METHOD FOR MANUFACTURING ORGANIC ELECTROLUMINESCENT DISPLAY APPARATUS

(75) Inventors: Atsushi Shiozaki, Mobara-shi (JP); Toshihiko Mimura, Tokyo (JP); Noriyuki Kaifu, Mobara-shi (JP); Katsunori Oya, Chiba-shi (JP); Tetsuya Karaki, Kawasaki-shi (JP)

(73) Assignee: CANON KABUSHIKI KAISHA, Tokyo (JP)

(21) Appl. No.: 13/320,827

(22) PCT Filed: May 13, 2010
(86) PCT No.: PCT/JP2010/003256

§ 371 Date: Nov. 16, 2011

(30) Foreign Application Priority Data
May 20, 2009 (JP) 2009-122128

(51) Int. Cl. H01L 51/56

(52) U.S. Cl. 438/35; 257/E51.022

(57) ABSTRACT

Provided is a method for manufacturing an organic electroluminescent display apparatus that includes a substrate and a plurality of pixels each including two or more types of sub-pixels, in which the pixels are arranged in a display area of the substrate, and, among the sub-pixels, one type of sub-pixels are specified sub-pixels provided at certain intervals. The specified sub-pixels are formed by selectively forming the (2n-1)th specified sub-pixels (wherein n represents an integer of 1 or more) numbered from a side end of the display area using a mask having openings at positions corresponding to the (2n-1)th specified sub-pixels numbered from the side end, and selectively forming the (2n)th specified sub-pixels numbered from the side end using a mask having openings at positions corresponding to the (2n)th specified sub-pixels numbered from the side end.

### TECHNICAL FIELD

The present invention relates to a method for manufacturing an organic electroluminescent (EL) display apparatus.

### BACKGROUND ART

Organic electroluminescent (EL) display apparatuses are display apparatuses (displays) including organic electroluminescent (EL) elements, which are self light-emitting elements. Accordingly, not only is a backlight not necessary unlike in the case of liquid crystal displays, but also light weight and small thickness can be realized. Thus, organic electroluminescent display apparatuses have attracted attention as a next-generation display provided with good response speed, view angle, and color re-producibility.

The reason why organic electroluminescent display apparatuses have not been widely on the market though they have such excellent performances is that it is difficult to process organic compound layers (luminescent layers) having a luminous performance. In general, in order to manufacture a full-color organic electroluminescent display apparatus, it is necessary to separately forming respective luminescent colors (R, G, and B) of organic electroluminescent elements constituting the organic electroluminescent display apparatus. In order to separately form such organic electroluminescent elements for different colors, a vapor deposition process using a mask is usually employed particularly when the materials for luminescent layers are low-molecular-weight materials. However, the mask used in such a vapor deposition process is expensive. In addition, since the accuracy of the mask determines the accuracy of the organic electroluminescent display apparatus, such an organic electroluminescent display apparatus is not satisfactory from the standpoint of realizing high definition of the display apparatus, as compared with liquid crystal displays, the accuracy of which is determined by a photolithographic process.

Shadow masks used for manufacturing an organic electroluminescent display apparatus are broadly divided into plating masks formed by plating and etching masks formed by etching. Luminescent layers of organic electroluminescent elements whose luminescent color is any one of red, blue, and green and which constitute an organic electroluminescent display apparatus are formed using a shadow mask so that the luminescent layers of the respective luminescent colors are separately arranged. More specifically, a shadow mask used for forming a certain luminescent layer is placed between an evaporation source and a substrate having TFTs and other components thereon. The deposition time is controlled by opening and closing a shielding plate provided between the evaporation source and the shadow mask to form a luminescent layer having a predetermined thickness and pattern.

As for methods employed in this case, PTL 1 and PTL 2 specifically disclose methods for separately forming luminescent layers of respective colors by vapor deposition.

Meanwhile, recently, the increase in the definition of displays (organic electroluminescent display apparatuses) required for mobile devices and the like has rapidly advanced. For example, in a display corresponding to 3 inches, the video graphic array (VGA) specification (480 pixels in the vertical direction×640 pixels in the horizontal direction) has been generally used.

However, in the case where an organic electroluminescent display apparatus is fabricated in accordance with the VGA specification, openings of a shadow mask used for forming organic electroluminescent elements constituting the organic electroluminescent display apparatus have a pitch interval of 95 micrometers. In addition, when a luminescent layer is formed at predetermined positions of organic electroluminescent elements arranged in the organic electroluminescent display apparatus, the alignment accuracy between the mask and a substrate before the formation of the luminescent layer is important. This is because the value calculated by subtracting the alignment accuracy from the pitch interval of the openings of the shadow mask corresponds to the width of the luminescent layer constituting each of the organic electroluminescent display elements. In the case of the VGA specification, it is necessary to make the width of each opening of the luminescent layer 40 micrometers or less, and therefore, it is also necessary to design the width of each opening of the mask to be 40 micrometers or less.

In order to realize high definition of an organic electroluminescent display apparatus, it is necessary to reduce the film thickness of the mask in accordance with the width of the openings of the mask. This is because etching is used in the formation of the mask. That is, in producing a mask including openings having a narrow width, it is necessary to reduce the film thickness of the mask in order to ensure the accuracy of the mask. However, when the film thickness is reduced, the mechanical strength of the mask decreases. The decrease in the mechanical strength of the mask results in the problem that the mask is readily deformed when, for example, the mask is regularly cleaned in a liquid in order to remove a material constituting an organic electroluminescent (EL) layer and adhered to the mask so that the mask can be reused. More specifically, when the mask is taken out from a cleaning liquid, openings are attracted to each other by the surface tension of the cleaning liquid adhered to the openings of the mask. As a result, slit deformation is generated in the mask. Accordingly, when the film thickness of the mask is reduced, the lifetime of the mask is shortened, resulting in the problem of a significant increase in the production cost of the organic electroluminescent display apparatus.

In a known method for eliminating the above-described problem in terms of the film thickness of the mask, a film is formed on a surface of the mask by plating. In this case, the film thickness of the mask can be increased while ensuring a narrow width of the openings.

However, in this method, the cost increases, and the resulting mask is considerably expensive. In addition, NiCo, which is commonly used as such a film formed by plating, has a higher thermal expansion coefficient than that of Invar material, which is commonly used as the mask. Accordingly, in order to ensure the accuracy of the mask in use, it is necessary that the tension at which the mask is applied to a frame material be larger than that in the case of Invar material. Therefore, the resulting mask is readily subjected to plastic deformation. Accordingly, the yield in the manufacturing of the mask decreases and the mask itself becomes further expensive, resulting in a problem of significantly increasing the production cost of the organic electroluminescent display apparatus.

Furthermore, in the case where the film thickness of the mask is increased by the above plating method while ensuring a narrow width of the openings, the film thickness of organic electroluminescent elements varies depending on the angle of incidence of an evaporation substance proceeding from an evaporation source to an opening of the mask. This is because the evaporation source usually emits the evaporation substance from a point-like or linear opening that is sufficiently smaller than the mask. Accordingly, “shading” in which the evaporation substance bounces back off a wall surface of an opening of the mask occurs depending on the angle of incidence of the evaporation substance when the evaporation substance enter the opening of the mask. The thickness of the resulting pattern-formed thin film is varied by this shading. The occurrence of the shading depends on the film thickness of the mask and the angle of incidence when the evaporation substance enters the opening of the mask and does not depend on the width of the mask. However, the effect of the shading increases as the width of the opening of the mask deceases, and thus the shading significantly affects the color purity of organic electroluminescent panels.

Another conceivable method for increasing the strength of the mask is a method in which bridges are formed in openings of the mask at constant intervals. However, when such bridges are formed, the alignment accuracy of the mask depends not only on the alignment accuracy in the horizontal direction as in the usual method but also on the alignment accuracy in the vertical direction. As a result, it is necessary to form in advance openings of an organic luminescent layer of organic electroluminescent elements so as to have a reduced size not only in the horizontal direction but also in the vertical direction. Consequently, the opening ratio per pixel of a light-emitting portion of each organic electroluminescent element is significantly decreased.

### CITATION LIST

### Patent Literature

PTL 1: Japanese Patent Laid-Open No. 2002-110345

PTL 2: Japanese Patent Laid-Open No. 10-312884

### SUMMARY OF INVENTION

The present invention has been made to solve the above problems. The present invention provides a method for manufacturing an organic electroluminescent display apparatus in which the lifetime of a mask can be increased while ensuring the width of openings of the mask and the production efficiency can be improved.

Specifically, the present invention provides a method for manufacturing an organic electroluminescent display apparatus that includes a substrate and a plurality of pixels each including two or more types of sub-pixels, in which the pixels are arranged in a display area of the substrate, and, among the sub-pixels, one type of sub-pixels are specified sub-pixels that are provided at certain intervals. In the method, the specified sub-pixels are formed by the steps of (i) selectively forming the (2n-1)th specified sub-pixels (wherein n represents an integer of 1 or more) numbered from a side end of the display area using a mask having openings at positions corresponding to the (2n-1)th specified sub-pixels numbered from the side end; and (ii) selectively forming the (2n)th specified sub-pixels (wherein n represents an integer of 1 or more) numbered from the side end using a mask having openings at positions corresponding to the (2n)th specified sub-pixels numbered from the side end.

According to the present invention, it is possible to provide a method for manufacturing an organic electroluminescent display apparatus in which the lifetime of a mask can be increased while ensuring the width of openings of the mask and the production efficiency can be improved.

### BRIEF DESCRIPTION OF DRAWINGS

FIG. 1A is a schematic plan view showing a first example of an organic electroluminescent display apparatus manufactured by a method of the present invention.

FIG. 1B is a schematic cross-sectional view showing the first example of the organic electroluminescent display apparatus manufactured by the method of the present invention.

FIG. 2A is a schematic view showing a step of forming an organic electroluminescent layer in a method according to a first embodiment of the present invention.

FIG. 2B is a schematic view showing a step of forming an organic electroluminescent layer in the method according to the first embodiment of the present invention.

FIG. 3 is a graph showing the number of deformed slits generated after cleaning of three types of masks used in forming an organic electroluminescent layer corresponding to specified sub-pixels.

FIG. 4A is a schematic plan view showing a second example of an organic electroluminescent display apparatus manufactured by a method of the present invention.

FIG. 4B is a schematic cross-sectional view showing the second example of the organic electroluminescent display apparatus manufactured by the method of the present invention.

FIG. 5A is a schematic view showing a step of forming an organic electroluminescent layer in a method according to a second embodiment of the present invention.

FIG. 5B is a schematic view showing a step of forming an organic electroluminescent layer in the method according to the second embodiment of the present invention.

FIG. 5C is a schematic view showing a step of forming an organic electroluminescent layer in the method according to the second embodiment of the present invention.

FIG. 5D is a schematic view showing a step of forming an organic electroluminescent layer in the method according to the second embodiment of the present invention.

FIG. 6A is a schematic plan view showing a third example of an organic electroluminescent display apparatus manufactured by a method of the present invention.

FIG. 6B is a schematic cross-sectional view showing the third example of the organic electroluminescent display apparatus manufactured by the method of the present invention.

FIG. 7 is a schematic view showing a step of forming an organic electroluminescent layer in a method according to a third embodiment of the present invention.

FIG. 7B is a schematic view showing a step of forming an organic electroluminescent layer in the method according to the third embodiment of the present invention.

FIG. 7C is a schematic view showing a step of forming an organic electroluminescent layer in the method according to the third embodiment of the present invention.

FIG. 7D is a schematic view showing a step of forming an organic electroluminescent layer in the method according to the third embodiment of the present invention.

FIG. 8 is a schematic view of a mask used in forming a bank.

FIG. 9 is a schematic view of an apparatus for forming an organic electroluminescent layer used in Example 1.

FIG. 10A is a schematic cross-sectional view showing a step in a process of forming an organic electroluminescent layer and an upper electrode in Example 1.

FIG. 10B is a schematic cross-sectional view showing a step in the process of forming the organic electroluminescent layer and the upper electrode in Example 1.

FIG. 10C is a schematic cross-sectional view showing a step in the process of forming the organic electroluminescent layer and the upper electrode in Example 1.

FIG. 10D is a schematic cross-sectional view showing a step in the process of forming the organic electroluminescent layer and the upper electrode in Example 1.

FIG. 10E is a schematic cross-sectional view showing a step in the process of forming the organic electroluminescent layer and the upper electrode in Example 1.

FIG. 10F is a schematic cross-sectional view showing a step in the process of forming the organic electroluminescent layer and the upper electrode in Example 1.

FIG. 10G is a schematic cross-sectional view showing a step in the process of forming the organic electroluminescent layer and the upper electrode in Example 1.

FIG. 10H is a schematic cross-sectional view showing a step in the process of forming the organic electroluminescent layer and the upper electrode in Example 1.

FIG. 10I is a schematic cross-sectional view showing a step in the process of forming the organic electroluminescent layer and the upper electrode in Example 1.

FIG. 10J is a schematic cross-sectional view showing a step in the process of forming the organic electroluminescent layer and the upper electrode in Example 1.

FIG. 11A is a schematic view of a mask used in a step of forming a green (G) luminescent layer in Example 1.

FIG. 11B is a partially enlarged schematic view of portion XIB in FIG. 11A.

FIG. 12 is a schematic view showing an apparatus for forming an organic electroluminescent layer and an upper electrode used in Example 2.

FIG. 13A is a schematic cross-sectional view showing a step in a process of forming an organic electroluminescent layer and the upper electrode in Example 2.

FIG. 13B is a schematic cross-sectional view showing a step in the process of forming the organic electroluminescent layer and the upper electrode in Example 2.

FIG. 13C is a schematic cross-sectional view showing a step in the process of forming the organic electroluminescent layer and the upper electrode in Example 2.

FIG. 13D is a schematic cross-sectional view showing a step in the process of forming the organic electroluminescent layer and the upper electrode in Example 2.

FIG. 13E is a schematic cross-sectional view showing a step in the process of forming the organic electroluminescent layer and the upper electrode in Example 2.

FIG. 13F is a schematic cross-sectional view showing a step in the process of forming the organic electroluminescent layer and the upper electrode in Example 2.

FIG. 13G is a schematic cross-sectional view showing a step in the process of forming the organic electroluminescent layer and the upper electrode in Example 2.

FIG. 13H is a schematic cross-sectional view showing a step in the process of forming the organic electroluminescent layer and the upper electrode in Example 2.

FIG. 14A is a schematic view of a mask used in a step of forming a red (R) luminescent layer in Example 2.

FIG. 14B is a schematic view of a mask used in a step of forming a blue (B) luminescent layer in Example 2.

FIG. 15A is a schematic cross-sectional view showing a step in a process of forming an organic electroluminescent layer and an upper electrode in Example 3.

FIG. 15B is a schematic cross-sectional view showing a step in the process of forming the organic electroluminescent layer and the upper electrode in Example 3.

FIG. 15C is a schematic cross-sectional view showing a step in the process of forming the organic electroluminescent layer and the upper electrode in Example 3.

FIG. 15D is a schematic cross-sectional view showing a step in the process of forming the organic electroluminescent layer and the upper electrode in Example 3.

FIG. 15E is a schematic cross-sectional view showing a step in the process of forming the organic electroluminescent layer and the upper electrode in Example 3.

FIG. 15F is a schematic cross-sectional view showing a step in the process of forming the organic electroluminescent layer and the upper electrode in Example 3.

FIG. 15G is a schematic cross-sectional view showing a step in the process of forming the organic electroluminescent layer and the upper electrode in Example 3.

FIG. 15H is a schematic cross-sectional view showing a step in the process of forming the organic electroluminescent layer and the upper electrode in Example 3.

### DESCRIPTION OF EMBODIMENTS

### First Embodiment

First, an organic electroluminescent display apparatus manufactured by a method of the present invention will be described.

An organic electroluminescent display apparatus manufactured by a method of the present invention includes a substrate and a plurality of pixels each including two or more types of sub-pixels.

The organic electroluminescent display apparatus will now be described with reference to accompanying drawings.

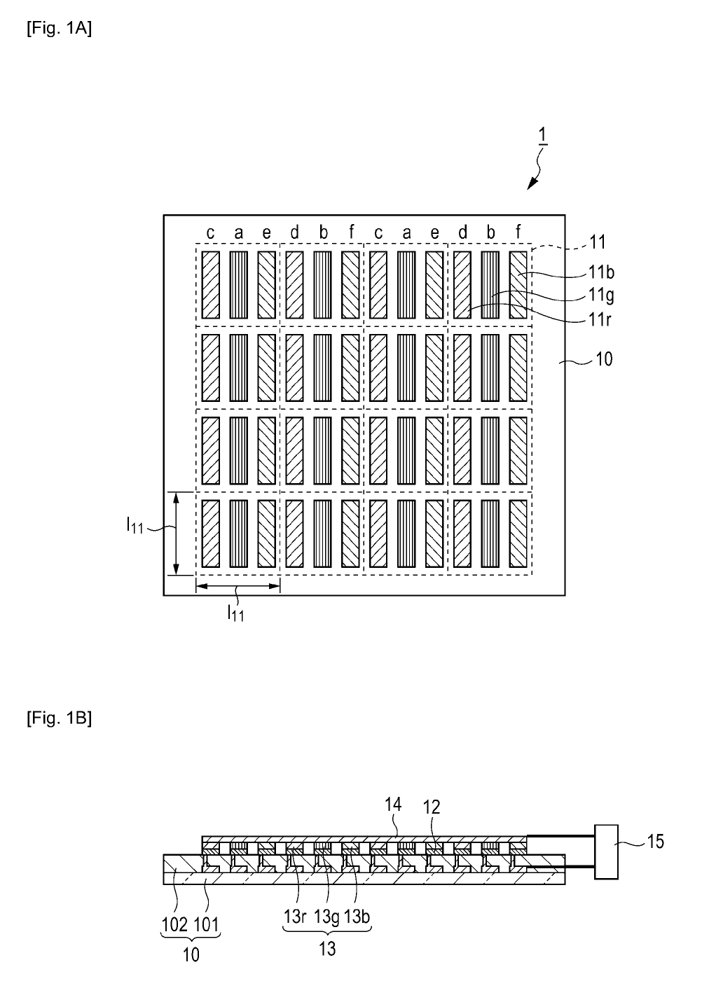

FIG. 1A is a schematic plan view showing a first example of an organic electroluminescent display apparatus manufactured by a method of the present invention. FIG. 1B is a schematic cross-sectional view of the organic electroluminescent display apparatus.

An organic electroluminescent display apparatus 1 shown in FIGS. 1A and 1B includes a substrate 10 and a plurality of pixels 11 arranged in a predetermined area of the substrate 10, more specifically, in a display area of the substrate 10. Herein, the term “arrange” specifically means that the pixels 11 are disposed in a matrix shape, as shown in FIG. 1A. In the description below, an area on the substrate 10 where the pixels 11 are provided may be referred to as “display area”.

Each of the pixels 11 constituting the organic electroluminescent display apparatus 1 is a component including a red (R) sub-pixel 11r, a green (G) sub-pixel 11g, and a blue (B) sub-pixel 11b. These three types of sub-pixels 11r, 11g, and 11b constituting a pixel 11 have a rectangular shape and are organic electroluminescent elements that emit red light, green light, and blue light, respectively. Each of these organic electroluminescent elements is an electronic element which is provided on the substrate 10 and in which a lower electrode 12, an organic electroluminescent layer 13, and an upper electrode 14 are stacked in that order. In the description below, the organic electroluminescent layer 13 may be referred to as organic electroluminescent layers 13r, 13g, and 13b corresponding to the sub-pixels 11r, 11g, and 11b, respectively.

In the organic electroluminescent display apparatus 1 shown in FIGS. 1A and 1B, an electrical signal is transmitted to the organic electroluminescent elements corresponding to the respective sub-pixels 11r, 11g, and 11b in units of pixels. Any one of the organic electroluminescent elements corresponding to the respective sub-pixels 11r, 11g, and 11b is driven by this electrical signal, whereby the organic electroluminescent display apparatus 1 shown in FIGS. 1A and 1B can perform a full-color display.

In the organic electroluminescent display apparatus 1 shown in FIGS. 1A and 1B, the sub-pixels 11r, 11g, and 11b constituting each pixel 11 have substantially the same area. Furthermore, the sub-pixels 11r, 11g, and 11b are uniformly aligned at certain intervals. In this embodiment, referring to FIGS. 1A and 1B, the alignment sequence of the sub-pixels is the order of RGBRGB from the left end of the display area, but the alignment sequence is not limited to thereto.

The organic electroluminescent display apparatus 1 shown in FIGS. 1A and 1B has a display area having, for example, a diagonal of about 3 inches and an aspect ratio (vertical-to-horizontal ratio) of 3:4, and includes 480 lines of each color in the horizontal direction and 640 lines of each color in the vertical direction. For convenience of explanation, some of the lines are shown in FIGS. 1A and 1B.

The driving method of the organic electroluminescent display apparatus 1 shown in FIGS. 1A and 1B may be a passive matrix method or an active matrix method. When the active matrix method is adopted, as shown in FIG. 1B, a substrate including a base 101 and TFT circuits 102 provided on the base 101 may be used as the substrate 10. In the organic electroluminescent display apparatus 1 shown in FIGS. 1A and 1B, each of the TFT circuits 102 is electrically connected to the corresponding lower electrode 12 to control electrical signals from an external circuit 15.

Next, a method for manufacturing the organic electroluminescent display apparatus 1 shown in FIGS. 1A and 1B will be described.

### Step of Preparing Substrate (First Embodiment)

First, a substrate 10, which is a component of an organic electroluminescent display apparatus, is prepared.

A base 101 composed of glass or the like may be used, as it is, as the substrate 10, and electrode layers and an organic electroluminescent layer may be formed on the base 101 in steps described below. In the case where the organic electroluminescent display apparatus is manufactured as an active matrix organic electroluminescent display apparatus, in this step, TFT circuits 102, namely, element circuits for driving respective organic electroluminescent elements and driving circuits for driving the element circuits are formed on the base 101. In this step, wiring for connecting the circuits to each other and connecting terminals for connecting the circuits to the outside are also formed.

The element circuits are formed in a display area where organic electroluminescent elements are formed in the subsequent steps. On the other hand, the driving circuits are formed outside the display area. Each of the circuits is formed using a thin-film transistor technology.

After the circuits, the wiring, and the connecting terminals are respectively formed, a protective film composed of SiN or the like and a planarizing film composed of an acrylic resin or the like are formed on each of the element circuits. After the formation of the protective film and the planarizing film, contact holes for electrical connection are formed using a photolithographic technique or the like.

Note that a substrate which is larger than one organic electroluminescent display apparatus 1 and on which element circuits of a plurality of organic electroluminescent display apparatuses 1 are formed in advance may also be used.

### Step of Forming Lower Electrode (First Embodiment)

Next, a lower electrode 12 is formed on the substrate 10. The lower electrode 12 may be a light-reflective electrode layer or a light-transmissive electrode layer. However, either the lower electrode 12 or an upper electrode 14 described below is a light-transmissive electrode layer.

In the case where the lower electrode 12 is formed as a light-transmissive electrode layer, specifically, a layer composed of a transparent oxide electrical conductor such as indium zinc oxide or indium tin oxide is used as the electrode layer. Alternatively, instead of the layer composed of a transparent oxide electrical conductor, a metal layer having a small thickness through which light is transmitted may be used. Alternatively, a laminate including such a layer composed of a transparent oxide electrical conductor and such a thin metal layer may also be used.

On the other hand, in the case where the lower electrode 12 is formed as a light-reflective electrode layer, specific examples of the electrode layer include metal thin films composed of a metal element or an alloy and laminates including such a metal thin film and a layer composed of a transparent oxide electrical conductor. A publicly known method can be employed as the method for forming the lower electrode 12.

After the lower electrode 12 is formed, a bank (not shown) composed of an acryl resin or the like may be formed. The bank defines exposed regions of the lower electrode 12 to define light-emitting regions of an organic electroluminescent layer formed in subsequent steps. In such a case, the bank may further be provided with a function of covering a difference in height due to the pattern of the lower electrode to prevent short-circuiting. In addition, the bank may also function as a spacer so that a mask used in a step of vapor deposition (step of forming an organic electroluminescent layer) described below does not contact a light-emitting portion such as the lower electrode 12.

Next, the resulting substrate on which the bank is optionally formed as described above is charged in a vacuum deposition apparatus to conduct a heat treatment or a surface treatment. The heat treatment is a heating step of removing moisture adhered to or adsorbed on the bank and the planarizing film. For example, a hot-wire treatment with a nichrome wire or the like can be performed as the heat treatment. The surface treatment is a step of cleaning the lower electrode. Specifically, for example, a UV treatment under reduced pressure is conducted.

### Step of Forming Organic Electroluminescent Layer (First Embodiment)

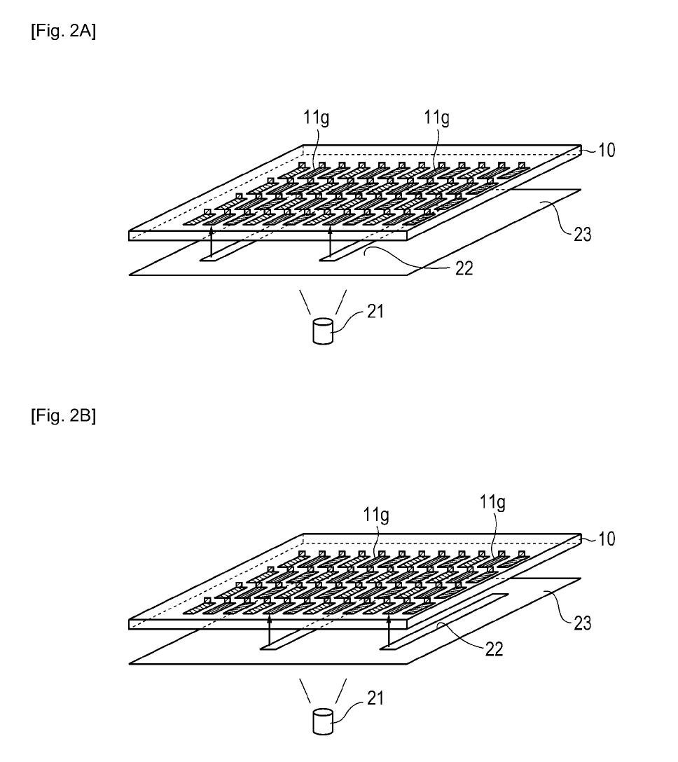

Next, an organic electroluminescent layer 13 is formed on the lower electrode 12. FIGS. 2A and 2B are schematic views each showing a step of forming an organic electroluminescent layer. As shown in FIGS. 2A and 2B, in these steps, the substrate 10 is placed so that a surface on which a film is to be deposited is disposed on the lower side. A material for the organic electroluminescent layer is then sequentially deposited from an evaporation source 21 disposed at the lower position to form the organic electroluminescent layer.

Prior to these steps, first, one type of sub-pixels among the sub-pixels shown in FIGS. 1A and 1B is specified as specified sub-pixels, and an organic electroluminescent layer corresponding to these specified sub-pixels is formed. Sub-pixels other than the specified sub-pixels each having a certain width are arranged in a certain pattern, and thus the specified sub-pixels are provided at certain intervals. Specifically, the specified sub-pixels are the R sub-pixels 11r, the G sub-pixels 11g, or the B sub-pixels 11b shown in FIG. 1A.

In the present invention, these specified sub-pixels are formed by steps (i) and (ii) below. In step (i), the (2n-1)th specified sub-pixels (wherein n represents an integer of 1 or more) numbered from a side end of the display area are selectively formed using a mask having openings at positions corresponding to the (2n-1)th specified sub-pixels numbered from the side end. In step (ii), the (2n)th specified sub-pixels (wherein n represents an integer of 1 or more) numbered from the side end are selectively formed using a mask having openings at positions corresponding to the (2n)th specified sub-pixels numbered from the side end.

In steps (i) and (ii) above, the term “side end of the display area” refers to the outer circumference of a pixel located at the leftmost side or the rightmost side when the organic electroluminescent display apparatus is viewed in plan. In the present invention, the side end of the display area may be the outer circumference at the right side of the pixel or the outer circumference at the left side of the pixel. Furthermore, in performing steps (i) and (ii), the order of the steps is not particularly limited.

A more specific method will now be described.

First, as shown in FIG. 2A, a mask 23 having openings 22 at positions corresponding to, among G sub-pixels 11g selected as the specified sub-pixels, the (2n-1)th G sub-pixels 11g numbered from the left end of the display area is aligned at a lower position of the substrate 10. Subsequently, a material for the organic electroluminescent layer 13 is evaporated from an evaporation source 21 to selectively form an organic electroluminescent layer corresponding to the (2n-1)th G sub-pixels 11g numbered from the left end of the display area. As a result, an organic electroluminescent layer 13g corresponding to the sub-pixels located at positions “a” in FIG. 1A is formed.

Next, as shown in FIG. 2B, a mask 23 having openings 22 at positions corresponding to, among G sub-pixels 11g, the (2n)th G sub-pixels 11g numbered from the left end of the display area is aligned at a lower position of the substrate 10. Subsequently, the material for the organic electroluminescent layer 13 is evaporated from the evaporation source 21 to selectively form an organic electroluminescent layer corresponding to the (2n)th G sub-pixels 11g numbered from the left end of the display area. As a result, an organic electroluminescent layer 13g corresponding to the sub-pixels located at positions “b” in FIG. 1A is formed.

Next, a mask 23 having openings 22 at positions corresponding to, among R sub-pixels 11r, the (2n-1)th R sub-pixels 11r numbered from the left end of the display area is aligned at a lower position of the substrate 10. Subsequently, a material for the organic electroluminescent layer 13 is evaporated from an evaporation source 21 to selectively form an organic electroluminescent layer corresponding to the (2n-1)th R sub-pixels 11r numbered from the left end of the display area. As a result, an organic electroluminescent layer 13r corresponding to the sub-pixels located at positions “c” in FIG. 1A is formed.

Next, a mask 23 having openings 22 at positions corresponding to, among R sub-pixels 11r, the (2n)th R sub-pixels 11r numbered from the left end of the display area is aligned at a lower position of the substrate 10. Subsequently, the material for the organic electroluminescent layer 13 is evaporated from the evaporation source 21 to selectively form an organic electroluminescent layer corresponding to the (2n)th R sub-pixels 11r numbered from the left end of the display area. As a result, an organic electroluminescent layer 13r corresponding to the sub-pixels located at positions “d” in FIG. 1A is formed.

Next, a mask 23 having openings 22 at positions corresponding to, among B sub-pixels 11b, the (2n-1)th B sub-pixels 11b numbered from the left end of the display area is aligned at a lower position of the substrate 10. Subsequently, a material for the organic electroluminescent layer 13 is evaporated from an evaporation source 21 to selectively form an organic electroluminescent layer corresponding to the (2n-1)th B sub-pixels 11b numbered from the left end of the display area. As a result, an organic electroluminescent layer 13b corresponding to the sub-pixels located at positions “e” in FIG. 1A is formed.

Next, a mask 23 having openings 22 at positions corresponding to, among B sub-pixels 11b, the (2n)th B sub-pixels 11b numbered from the left end of the display area is aligned at a lower position of the substrate 10. Subsequently, the material for the organic electroluminescent layer 13 is evaporated from the evaporation source 21 to selectively form an organic electroluminescent layer corresponding to the (2n)th B sub-pixels 11b numbered from the left end of the display area. As a result, an organic electroluminescent layer 13b corresponding to the sub-pixels located at positions “f” in FIG. 1A is formed.

An organic electroluminescent layer corresponding to the respective sub-pixels is formed through the above-described steps.

In the steps of forming the organic electroluminescent layer 13g corresponding to the G sub-pixels 11g, the organic electroluminescent layer 13g may be formed in the order of “a” and “b” or in the order of “b” and “a” shown in FIG. 1A. Similarly, in the steps of forming the organic electroluminescent layer 13r corresponding to the R sub-pixels 11r, the organic electroluminescent layer 13r may be formed in the order of “c” and “d” or in the order of “d” and “c” shown in FIG. 1A. Similarly, in the steps of forming the organic electroluminescent layer 13b corresponding to the B sub-pixels 11b, the organic electroluminescent layer 13b may be formed in the order of “e” and “f” or in the order of “f” and “e” shown in FIG. 1A.

Each of the organic electroluminescent layers 13g, 13r, and 13b formed in these steps is a layer composed of a laminate in which one or a plurality of layers containing at least a luminescent layer are stacked. In these steps, when the organic electroluminescent layers 13g, 13r, and 13b corresponding to the sub-pixels 11g, 11r, and 11b, respectively, and shown by “a” to “f” in FIG. 1A, separate masks are preferably used in consideration of the lifetime of the masks. Specifically, when the organic electroluminescent layers 13g, 13r, and 13b are formed, six masks are preferably prepared in total.

However, in the case where an organic compound layer other than the luminescent layer is formed as a layer common to the respective types of sub-pixels, it is not necessary to use a mask in forming the layer other than the luminescent layer, and thus the same mask may be used when sub-pixels of the same color are formed. In such a case, the same mask can be used in the steps of forming the luminescent layers of respective colors by vapor deposition and the number of masks used can be reduced, though the manufacturing throughput decreases. In addition, a single deposition apparatus may be used in the steps of forming the luminescent layer of the same color. In such a case, the organic electroluminescent layer can be deposited using the same material charged in the single deposition apparatus, and the material for the organic electroluminescent layer can be deposited in a state in which the volume of the material in a crucible in the deposition apparatus does not significantly vary. As a result, it is possible to prevent, in advance, problems such as variations in color due to a difference in the lot of the material, and variations in the luminance due to variations in the film thickness that are caused by a difference in the deposition rate due to variations in the volume of the material in the crucible.

In the formation of the organic electroluminescent layer corresponding to respective types of sub-pixels by vapor deposition, the width of openings of a mask may be changed in respective types of sub-pixels.

The mask used in forming the organic electroluminescent layer corresponding to respective sub-pixels preferably has a pitch of openings of 95 micrometers or more and a width of the openings of 40 micrometers or less. In the formation of the organic electroluminescent layer corresponding to respective sub-pixels, it is necessary to control the thickness of the mask to be less than about 1.2 times the width of the openings from the standpoint of processing accuracy. However, when the width of the openings of the mask is 40 micrometers or less, the thickness of the mask is less than 50 micrometers. As a result, the mechanical strength of the mask itself significantly decreases. To solve this problem, the pitch of the openings of the mask is controlled to be 95 micrometers or more, thereby suppressing the occurrence of slit deformation during cleaning of the mask. Note that the term “pitch” represents the interval between adjacent openings of the mask. More specifically, the pitch is the sum of the width of an opening of the mask and the distance between adjacent openings of the mask.

As described above, in the above steps, in forming the organic electroluminescent layer corresponding to at least specified sub-pixels, a mask in which openings are provided so that the organic electroluminescent layer is alternately formed is used. As a result, the distance between adjacent openings of the mask can be increased twofold or more, as compared with masks in the related art. Accordingly, the mechanical strength of the mask itself increases, thereby improving the lifetime of the mask, even in the case where the mask has a small thickness.

The mask used in forming the organic electroluminescent layer is cleaned and reused.

In this case, during the cleaning of the mask, some of the openings of the mask may deform in some cases. This deformation is called slit deformation, which is a factor that determines the lifetime of the mask. The slit deformation can be corrected in a step after the mask is cleaned. However, each time the slit deformation is corrected, mechanical deformation of the mask itself occurs, and the possibility of slit deformation not being correctable increases. When such slit deformation that is uncorrectable is generated even at one position, the mask cannot be used any more. Accordingly, the lifetime of the mask is represented by the product of the probability in which uncorrectable slit deformation is generated per slit deformation. Thus, the lifetime of the mask is more affected by this product than the difference in the number of deformed slits.

On the other hand, when the organic electroluminescent layer corresponding to at least specified sub-pixels is separately formed in two steps, the following two methods of using the mask are conceivable.

(1) A method in which the same mask is used twice.

(2) A method in which different masks are respectively used in a first step and a second step.

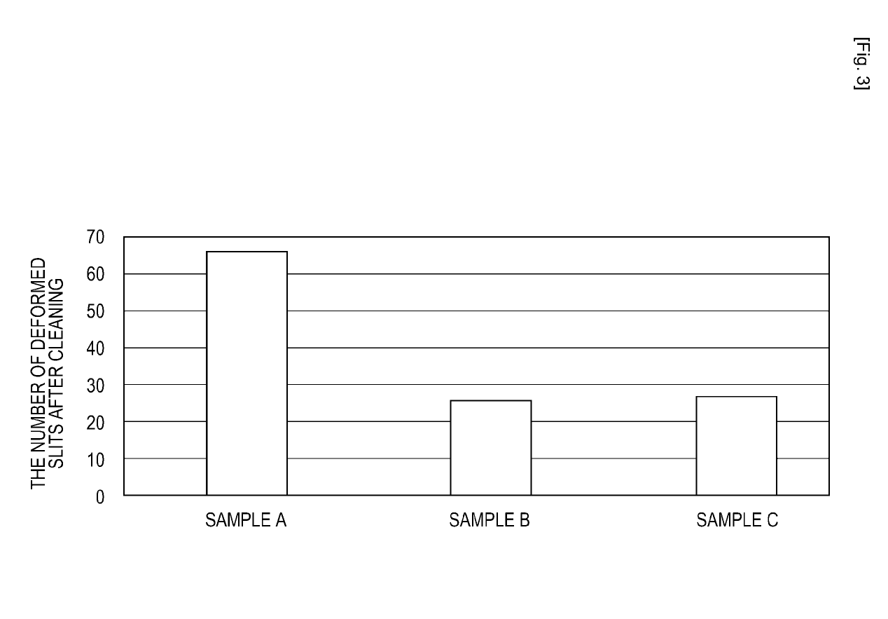

FIG. 3 is a graph showing the number of deformed slits generated after cleaning of three types of masks used in forming an organic electroluminescent layer corresponding to specified sub-pixels. The vertical axis of this graph represents the number of deformed slits. Naturally, the smaller this number, the larger the number of times the mask can be reused.

In the graph shown in FIG. 3, samples A to C are masks described below. Note that masks used as the original of samples A to C are common in that they have a film thickness of 0.03 mm and have a 3-inch VGA specification.
Sample A: A mask used when specified sub-pixels were formed by the method (1) above.
Sample B: Out of masks used when specified sub-pixels were formed by the method (2) above, the mask used in the first step.
Sample C: Out of masks used when specified sub-pixels were formed by the method (2) above, the mask used in the second step.

The graph in FIG. 3 shows that the number of deformed slits per mask in sample B and sample C is less than half of that of sample A. This result shows that the lifetime of the mask can be improved by at least two times by changing the mask used when the organic electroluminescent layer corresponding to specified sub-pixels is formed.

In the above steps, masks having openings, each of which is continuous in the vertical direction, can be used in at least steps (i) and (ii). By using such masks having openings, each of which is continuous in the vertical direction, the alignment accuracy in the vertical direction can be decreased. As a result, masks suitable for high definition and having a high opening ratio can be used, and therefore, an organic electroluminescent display apparatus with high definition and long lifetime can be manufactured. In addition, the lifetime of the masks can also be ensured by using masks having openings, each of which is continuous in the vertical direction.

In the above steps, in at least steps (i) and (ii), the same evaporation source can be used. In such a case, even when the process of forming the organic electroluminescent layer corresponding to sub-pixels of the same color is separately performed in two steps, variations in the film thickness and the composition of the material can be minimized. The reason for this is as follows. An organic electroluminescent layer material generated and evaporated from an evaporation source is significantly affected by the amount of material remaining in the evaporation source, the temperature of the evaporation source, and the like. Accordingly, when a plurality of evaporation sources are separately provided in the formation of the organic electroluminescent layer, the deposition rate and the like are considerably difficult to be controlled and may significantly vary. To prevent this problem, by using the same evaporation source in forming the organic electroluminescent layer of the same color, the organic electroluminescent layer can be formed under an environment in which the evaporated organic electroluminescent material is generated from the evaporation source at substantially the same time in both the first and second deposition steps. Accordingly, the organic electroluminescent layer corresponding to sub-pixels of the same color can be formed so that the film thickness and the composition of the material are uniform.

### Step of Forming Upper Electrode (First Embodiment)

After the organic electroluminescent layer 13 is formed, an upper electrode 14 is formed on the organic electroluminescent layer 13. As described above, the upper electrode 14 may be a light-transmissive electrode layer or a light-reflective electrode layer as in the lower electrode 12. It is necessary that either the lower electrode 12 or the upper electrode 14 be used as an anode or a cathode, however, either one may be used. The lower electrode 12 may be connected to an element circuit, and the upper electrode 14 may be connected to common wiring. Alternatively, the upper electrode 14 may be individually provided for each sub-pixel. Specifically, such an upper electrode 14 is individually formed as follows. A contact hole is formed by performing laser ablation in a part of the organic electroluminescent layer 13, and an upper electrode 14 is formed as an individual electrode for an element using a mask and is connected to an element circuit.

### Sealing Step (First Embodiment)

In the organic electroluminescent display apparatus manufactured by the method of the present invention, the electrode layers and the organic electroluminescent layer constituting the display apparatus can be protected from moisture and oxygen in the atmosphere using a sealing member.

For example, components other than connecting terminals are covered with a glass cap and the substrate is bonded to the glass cap with an adhesive, thereby blocking the organic electroluminescent elements constituting the sub-pixels from the outside air. Thus, the organic electroluminescent display apparatus is manufactured. Note that the organic electroluminescent elements may be blocked from the outside air by providing a protective film composed of SiN or the like instead of using such a glass cap.

Subsequently, a power supply, image signals, and driving signals are supplied from an external circuit to the manufactured organic electroluminescent display apparatus to switch TFT circuits, thus displaying desired images on the display area.

### Second Embodiment

Next, a second embodiment of the present invention will be described. First, an organic electroluminescent display apparatus manufactured in this embodiment will be described.

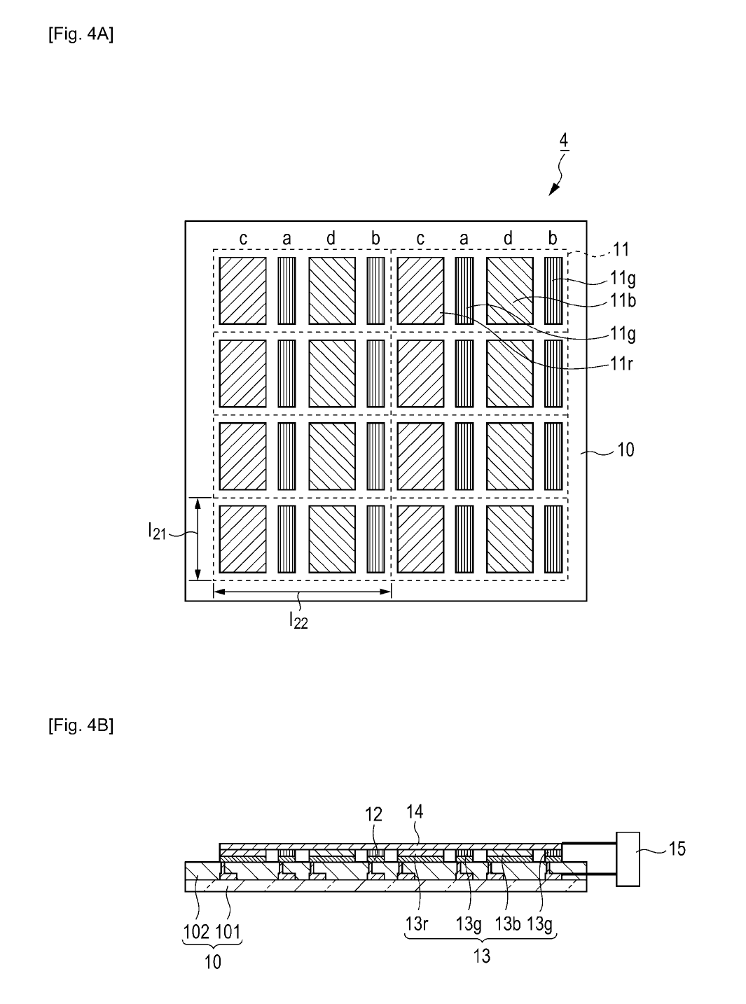

FIG. 4A is a schematic plan view showing a second example of an organic electroluminescent display apparatus manufactured by a method of the present invention. FIG. 4B is a schematic cross-sectional view of the organic electroluminescent display apparatus. Components the same as those of the organic electroluminescent display apparatus 1 shown in FIGS. 1A and 1B are assigned the same reference numerals. The difference from the first example described in the first embodiment will be mainly described below.

An organic electroluminescent display apparatus 4 shown in FIGS. 4A and 4B has an alignment pattern of sub-pixels of, from the left of a display area, RGBGRGBG. However, two G sub-pixels included in one pixel can be respectively driven by separate signals. Accordingly, the G sub-pixels can be driven by signals that produce a definition two times finer than that produced for R sub-pixels and B sub-pixels. In this embodiment, for example, in a display apparatus having a diagonal of about 3 inches, it is possible to provide a configuration including 640 lines of G sub-pixels with a pitch (repetition interval) of 96 micrometers in the column direction, and 320 lines of R sub-pixels and 320 lines of B sub-pixels each having a pitch of 192 micrometers in the column direction.

Next, this embodiment will be specifically described. In the description below, the difference from the first embodiment will be mainly described.

In this embodiment, steps other than the steps of forming an organic electroluminescent layer can be conducted as in the first embodiment.

### Step of Forming Organic Electroluminescent Layer (Second Embodiment)

When an organic electroluminescent layer is formed in this embodiment, for example, G sub-pixels are selected as specified sub-pixels, and an organic electroluminescent layer corresponding to the G sub-pixels is formed by steps (i) and (ii) described above.

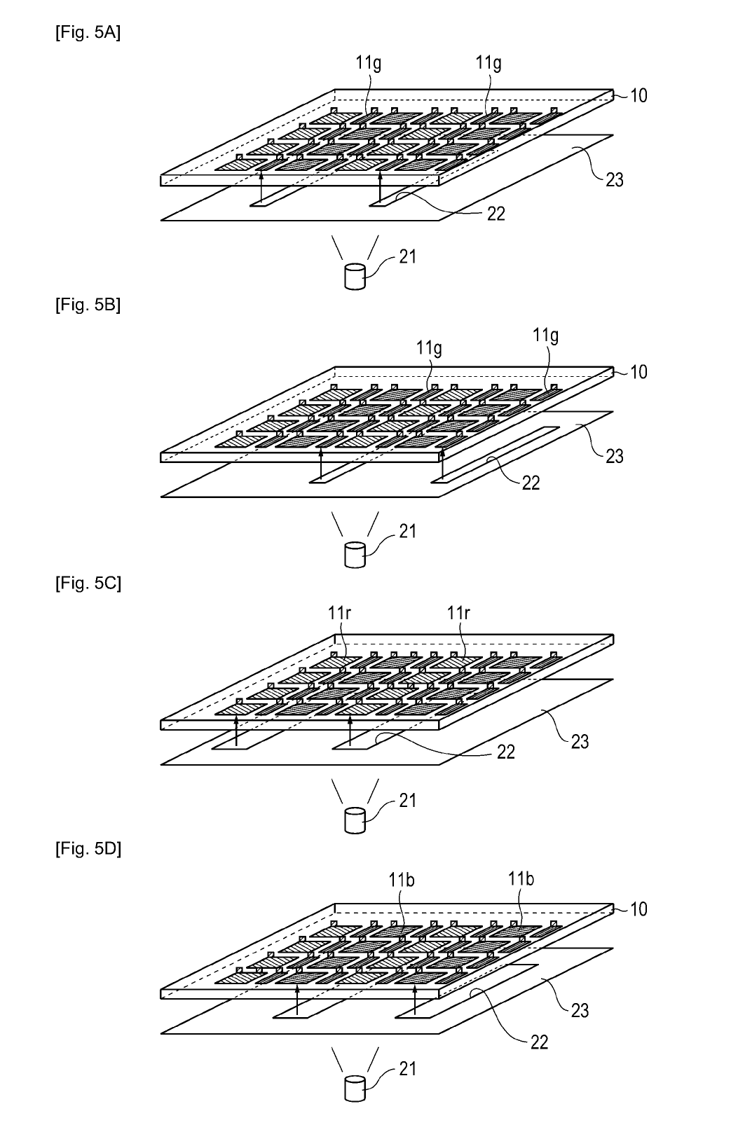

Specifically, first, as shown in FIG. 5A, a mask 23 having openings 22 at positions corresponding to, among G sub-pixels 11g, the (2n-1)th G sub-pixels 11g numbered from the left end of the display area is aligned at a lower position of a substrate 10. Subsequently, a material for an organic electroluminescent layer 13 is evaporated from an evaporation source 21 to selectively form an organic electroluminescent layer corresponding to the (2n-1)th G sub-pixels 11g numbered from the left end of the display area. As a result, an organic electroluminescent layer 13g corresponding to the sub-pixels located at positions “a” in FIG. 4A is formed.

Next, as shown in FIG. 5B, a mask 23 having openings 22 at positions corresponding to, among G sub-pixels 11g, the (2n)th G sub-pixels 11g numbered from the left end of the display area is aligned at a lower position of the substrate 10. Subsequently, the material for the organic electroluminescent layer 13 is evaporated from the evaporation source 21 to selectively form an organic electroluminescent layer corresponding to the (2n)th G sub-pixels 11g numbered from the left end of the display area. As a result, an organic electroluminescent layer 13g corresponding to the sub-pixels located at positions “b” in FIG. 4A is formed.

As in the first embodiment, in conducting steps (i) and (ii), the order of the steps is not particularly limited.

After step (ii) is conducted, R sub-pixels and B sub-pixels are sequentially formed by steps (iii) and (iv) described below.
(iii) Step of forming R sub-pixels
(iv) Step of forming B sub-pixels

In step (iii), specifically, as shown in FIG. 5C, a mask 23 having openings 22 at positions corresponding to R sub-pixels 11r is aligned at a lower position of the substrate 10, and a material for the organic electroluminescent layer 13 is evaporated from an evaporation source 21. As a result, an organic electroluminescent layer 13r corresponding to the R sub-pixels 11r located at positions “c” in FIG. 4A is formed.

In step (iv), specifically, as shown in FIG. 5D, a mask 23 having openings 22 at positions corresponding to B sub-pixels 11b is aligned at a lower position of the substrate 10, and a material for the organic electroluminescent layer 13 is evaporated from an evaporation source 21. As a result, an organic electroluminescent layer 13b corresponding to the B sub-pixels 11b located at positions “d” in FIG. 4A is formed.

In this embodiment, as shown in FIGS. 5A to 5D, the width of the openings of the masks used for forming organic electroluminescent elements corresponding to the R sub-pixels and the B sub-pixels is larger than the width of the openings of the mask used for forming organic electroluminescent elements corresponding to the G sub-pixels. That is, in this embodiment, the G sub-pixels are provided so as to have a small width, and the R sub-pixels and the B sub-pixels are provided so as to have a large width. According to this structure, the number of masks used and the number of steps of separately forming the organic electroluminescent layer can be reduced while ensuring the lifetime of the masks and without significantly degrading the feeling of resolution of the display.

The reason why the width of the G sub-pixels 11g is narrowed is that the visibility of human is the most sensitive to green. That is, the reason is that when at least the organic electroluminescent elements corresponding to the G sub-pixels are arranged on the substrate 10 with a high-definition pitch, a viewer can view images displayed on the display apparatus without a significant degradation of the feeling of resolution.

In this embodiment, the pitch of the openings of the masks used for forming the organic electroluminescent elements corresponding to the R sub-pixels and the B sub-pixels is the same as the pitch of the openings of the mask used for forming the organic electroluminescent elements corresponding to the G sub-pixels. As a result, the masks used for forming the organic electroluminescent elements corresponding to the R sub-pixels and the B sub-pixels can have a mask strength that is equivalent to or higher than that of the mask used for forming the organic electroluminescent elements corresponding to the G sub-pixels. Furthermore, it is sufficient that each of the masks used for forming the organic electroluminescent elements corresponding to the R sub-pixels and the B sub-pixels is used once. Accordingly, in this embodiment, the total number of times a mask is used in the steps of forming the organic electroluminescent layer is four, thus reducing the production cost.

On the other hand, in this embodiment, the mask used in step (i) and the mask used in step (ii) are preferably different. In this embodiment, in the steps of forming the respective types of sub-pixels, the number of steps of forming the organic electroluminescent layer is different. Therefore, in the formation of the organic electroluminescent layer of the G sub-pixels 11g, which requires a large number of steps, masks are prepared so that the number of masks is equal to the number of steps of forming the organic electroluminescent layer. In this case, all the steps of forming an organic electroluminescent layer of each color can be performed at the same time. Accordingly, the manufacturing process can be carried out at a constant speed without disruption of the respective steps.

### Third Embodiment

Next, a third embodiment of the present invention will now be described. First, an organic electroluminescent display apparatus manufactured in this embodiment will be described.

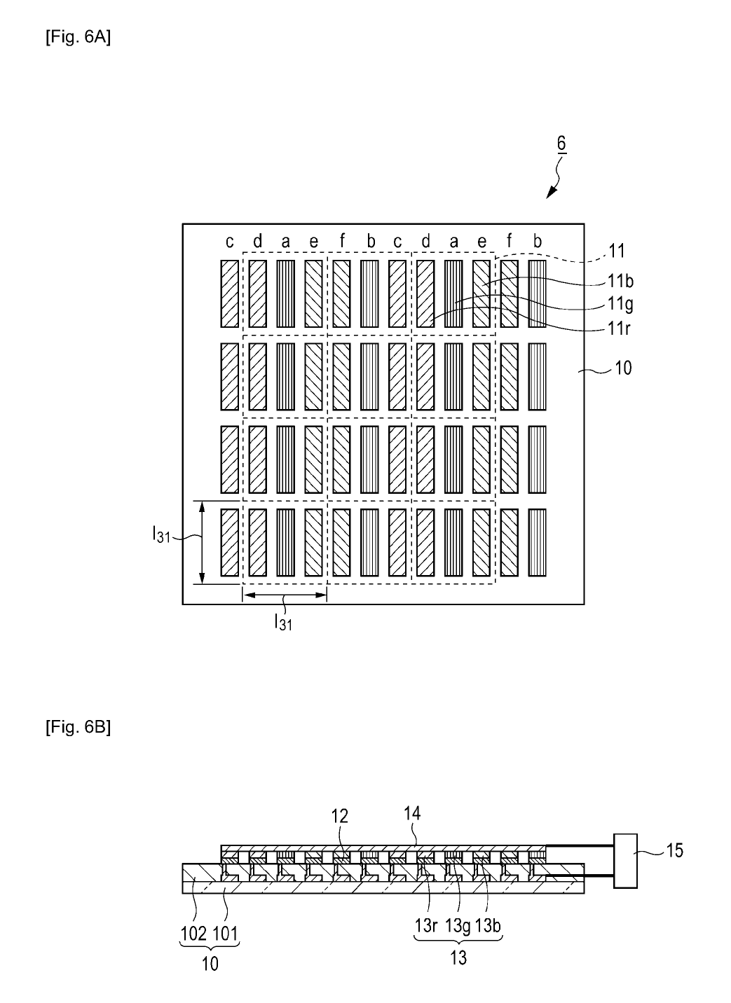

FIG. 6A is a schematic plan view showing a third example of an organic electroluminescent display apparatus manufactured by a method of the present invention. FIG. 6B is a schematic cross-sectional view of the organic electroluminescent display apparatus. Components the same as those of the organic electroluminescent display apparatus 1 shown in FIGS. 1A and 1B are assigned the same reference numerals. The difference from the first example described in the first embodiment will be mainly described below.

An organic electroluminescent display apparatus 6 shown in FIGS. 6A and 6B has an alignment pattern of sub-pixels of, from the left of the display area, (R)RGBBGRRGBBGR.

Next, this embodiment will be specifically described. In the description below, the difference from the first embodiment will be mainly described.

In this embodiment, steps other than the steps of forming an organic electroluminescent layer can be conducted as in the first embodiment.

### Step of Forming Organic Electroluminescent Layer (Third Embodiment)

When an organic electroluminescent layer is formed in this embodiment, for example, G sub-pixels are selected as specified sub-pixels, and an organic electroluminescent layer corresponding to the G sub-pixels is formed by steps (i) and (ii) described above.

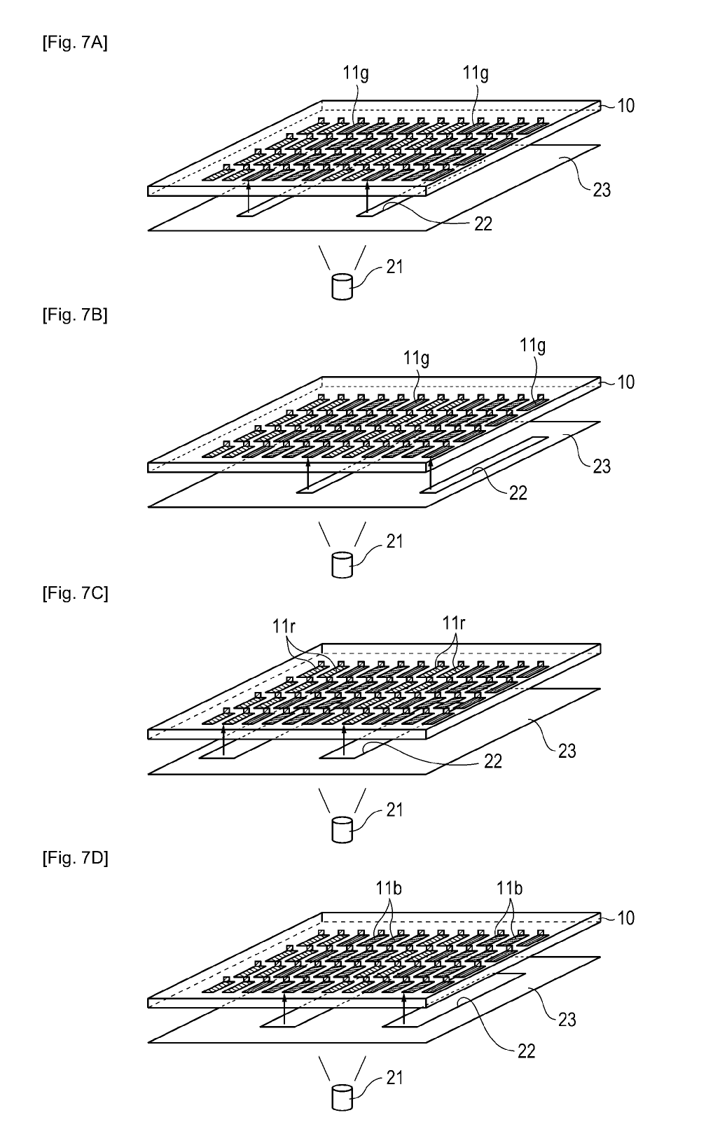

Specifically, first, as shown in FIG. 7A, a mask 23 having openings 22 at positions corresponding to, among G sub-pixels 11g, the (2n-1)th G sub-pixels 11g numbered from the left end of the display area is aligned at a lower position of a substrate 10. Subsequently, a material for an organic electroluminescent layer 13 is evaporated from an evaporation source 21 to selectively form an organic electroluminescent layer corresponding to the (2n-1)th G sub-pixels 11g numbered from the left end of the display area. As a result, an organic electroluminescent layer 13g corresponding to the sub-pixels 11g located at positions “a” in FIG. 6A is formed.

Next, as shown in FIG. 7B, a mask 23 having openings 22 at positions corresponding to, among G sub-pixels 11g, the (2n)th G sub-pixels 11g numbered from the left end of the display area is aligned at a lower position of the substrate 10. Subsequently, the material for the organic electroluminescent layer 13 is evaporated from the evaporation source 21 to selectively form an organic electroluminescent layer corresponding to the (2n)th G sub-pixels 11g numbered from the left end of the display area. As a result, an organic electroluminescent layer 13g corresponding to the sub-pixels 11g located at positions “b” in FIG. 6A is formed.

As in the first embodiment, in conducting steps (i) and (ii), the order of the steps is not particularly limited. Because of the same reason as that in the second embodiment, also in this embodiment, the mask used in step (i) and the mask used in step (ii) are preferably different.

After step (ii) is conducted, R sub-pixels and B sub-pixels are sequentially formed by steps (v) and (vi) described below.

(v) Step of forming R sub-pixels

(vi) Step of forming B sub-pixels

In step (v), specifically, as shown in FIG. 7C, a mask 23 having openings 22 at positions corresponding to R sub-pixels 11r is aligned at a lower position of the substrate 10, and a material for the organic electroluminescent layer 13 is evaporated from an evaporation source 21. As a result, an organic electroluminescent layer 13r corresponding to the R sub-pixels 11r located at positions “c” and “d” in FIG. 6A is formed at the same time.

In step (vi), specifically, as shown in FIG. 7D, a mask 23 having openings 22 at positions corresponding to B sub-pixels 11b is aligned at a lower position of the substrate 10, and a material for the organic electroluminescent layer 13 is evaporated from an evaporation source 21. As a result, an organic electroluminescent layer 13b corresponding to the B sub-pixels 11b located at positions “e” and “f” in FIG. 6A is formed at the same time.

According to this embodiment, for example, in a display apparatus having a diagonal of about 3 inches, it is possible to provide a configuration including 640 lines of the respective types of sub-pixels with a pitch of 96 micrometers in the column direction.

The number of times a mask is used and the number of times of vapor deposition in this embodiment are the same as those in the second embodiment. However, since the number of R sub-pixels, the number of G sub-pixels, and the number of B sub-pixels are the same in each row, this embodiment is advantageous in that the feeling of resolution can be improved compared with the second embodiment.

In this embodiment, each of the light emission area of the R sub-pixels and the light emission area of the B sub-pixels is usually larger than the light emission area of the G sub-pixels. This is because, in the same type of adjacent sub-pixels (namely, between B and B, and between R and R), it is not necessary that the layout is used in consideration of the accuracy of the mask and the distance between the sub-pixels. Therefore, in this embodiment, the distance between adjacent sub-pixels of the same type can be smaller than the distance between adjacent sub-pixels of different types (namely, between B and G, and between R and G). Accordingly, since the distance between adjacent sub-pixels of the same type can be reduced as compared with the method described in the first embodiment, the area corresponding to this distance can be utilized so as to increase the light emission area of organic electroluminescent elements corresponding to the sub-pixels. As a result, the light emission area of the organic electroluminescent elements corresponding to the R sub-pixels and the B sub-pixels is increased.

On the other hand, the above-described increase in the light emission area of the organic electroluminescent elements can be utilized so as to increase the light emission area of organic electroluminescent elements corresponding to different types of sub-pixels. In such a case, in particular, the increase in the light emission area is preferably utilized so as to increase the light emission area of organic electroluminescent elements corresponding to the G sub-pixels. In this case, the light emission area of the G sub-pixels themselves can be increased while ensuring the distance between the G sub-pixels and other types of sub-pixels. When the light emission area of the G sub-pixels can be increased, the width of openings of the mask corresponding to the G sub-pixels is also increased and the film thickness of the mask used in the vapor deposition can be increased. When the film thickness of the mask is increased, slit deformation does not tend to occur in the step of cleaning the mask, which is advantageous in that the lifetime of the mask is extended.

This embodiment is also advantageous in terms of electric power consumption. The reason for this is as follows. By increasing the light emission area of the organic electroluminescent elements corresponding to the G sub-pixels, the amount of current supplied per unit light emission area decreases, and thus the voltage applied between organic electroluminescent elements when the same amount of current is supplied decreases. Furthermore, the organic electroluminescent elements corresponding to the G sub-pixels significantly contribute to luminance signals, and in typical image signals, the current supplied to the organic electroluminescent elements corresponding to the G sub-pixels is significantly larger than the current supplied to the organic electroluminescent elements corresponding to the R sub-pixels and the B sub-pixels. Therefore, this is also advantageous in that the largest effect of decreasing the electric power consumption can be achieved.

Note that the order of the formation of the luminescent layers of the respective colors is not particularly limited.

### EXAMPLE 1

The organic electroluminescent display apparatus shown in FIGS. 1A and 1B was manufactured by the method of the first embodiment. The specific method will now be described with adequate reference to the drawings.

In Example 1, total twenty organic electroluminescent display apparatuses arranged in 4 rows and 5 columns were manufactured at the same time on a glass substrate having dimensions of 360 mm in the vertical direction and 460 mm in the horizontal direction. Here, each of the organic electroluminescent display apparatuses manufactured has a diagonal of about 3 inches and includes 480 pixels in the vertical direction and 640 pixels in the horizontal direction. Each of the pixels includes three types of stripe-shaped sub-pixels aligned in the order of RGB. The shape of each pixel is a square having a side (l₁₁) of 96 micrometers, and an organic electroluminescent element corresponding to one sub-pixel is provided in an area of 96 micrometers in the vertical direction and 32 micrometers in the horizontal direction.

### STEP OF PREPARING SUBSTRATE (EXAMPLE 1)

A barrier layer (not shown) was formed on the glass substrate (base 101). Specifically, a silicon nitride (SiN) layer with a thickness of 200 nm was formed by a plasma chemical vapor deposition (CVD) method using SiH₄, NH₃, and H₂ as source gas.

Next, a thin film composed of amorphous silicon and having a thickness of 50 nm was formed on the barrier layer by a plasma CVD method. Here, this amorphous silicon thin film functions as a channel layer. Next, the amorphous silicon was poly-crystallized by laser annealing and then processed to have predetermined shapes by patterning using a photolithographic technique. Thus, channel layers of transistors for driving, switching, and control circuits were respectively formed.

Next, silicon dioxide (SiO₂) was deposited on the channel layer by a CVD method to form a gate insulating film. In this step, the thickness of the gate insulating film was controlled to be 100 nm. Next, tantalum (Ta) and aluminum (Al) were sequentially deposited on the gate insulating film by a sputtering method or the like to form a laminate of the metal thin films. In this step, the thickness of the Ta thin film was controlled to be 50 nm, and the thickness of the Al thin film was controlled to be 200 nm. Next, the metal thin films were processed to have a predetermined shape by patterning using a photolithographic technique to form gate electrodes.

Next, regions other than N-regions of the channel layer were protected with a resist. The N-regions of the channel layer were then doped with phosphorus by an ion implantation technique. Next, regions other than P-regions of the channel layer were protected with a resist. The P-regions of the channel layer were then doped with boron by an ion implantation technique. Next, the channel layer was irradiated with a laser beam to activate the dopants.

Next, SiN was deposited on the channel layer and the gate electrodes by a plasma CVD method to form a protective film. In this step, the thickness of the protective film was controlled to be 500 nm. Next, contact holes for connection were formed at predetermined positions of the protective film by patterning using a photolithographic technique. Next, titanium (Ti) and a titanium-aluminum (TiAl) alloy were sequentially deposited on the protective film by a sputtering method to form an electrode layer having a two-layer structure. In this step, the film thickness of the Ti thin film was controlled to be 100 nm, and the film thickness of the TiAl alloy thin film was controlled to be 300 nm. Next, this electrode layer having the two-layer structure was processed to have predetermined shapes by patterning using a photolithographic technique. The processed electrode layer having the two-layer structure functions as any component of a source electrode, a drain electrode, a capacitor electrode, and a connecting terminal in accordance with the position thereof.

Next, SiN was deposited on the electrode layer having the two-layer structure by a CVD method to form a first interlayer insulating layer. In this step, the thickness of the first interlayer insulating layer was controlled to be 300 nm. Next, desired positions of the first interlayer insulating layer were etched by a photolithographic technique for connecting to a corresponding lower electrode.

Next, a second interlayer insulating layer was formed on the first interlayer insulating layer. An acrylic resin (PC415 manufactured by JSR Corporation) was applied onto the first interlayer insulating layer and spin-coated at a number of revolutions of 1,200 rpm to form a thin film. Subsequently, the thin film was pre-baked and then exposed at an illumination intensity of 100 mW/cm² with a photomask having a pattern of openings for electrically connecting each of the thin-film transistors to the corresponding lower electrode. Next, the thin film was developed with a developer (NMD-3 manufactured by Tokyo Ohka Kogyo Co., Ltd.) and then post-baked at 200 degrees Celsius to form the second interlayer insulating layer. The thickness of the second interlayer insulating layer was 1.5 micrometers. The substrate prepared by the method described above was used as a substrate 10 and used in steps described below.

### STEP OF FORMING LOWER ELECTRODE (EXAMPLE 1)

An aluminum-silicon (AlSi) alloy and indium tin oxide (ITO) were deposited in this order on the substrate 10 by a sputtering method or the like to form an electrode stacked thin film. In this step, the thickness of the AlSi thin film was controlled to be 50 nm, and the thickness of the ITO thin film was controlled to be 100 nm. Next, the electrode stacked thin film was processed by a photolithographic technique to form a lower electrode 12. The lower electrode 12 covered a portion connected to a thin-film transistor circuit and had a size having a length of 85 micrometers and a width of 25 micrometers, which was larger than the area where an organic electroluminescent layer described below was formed.

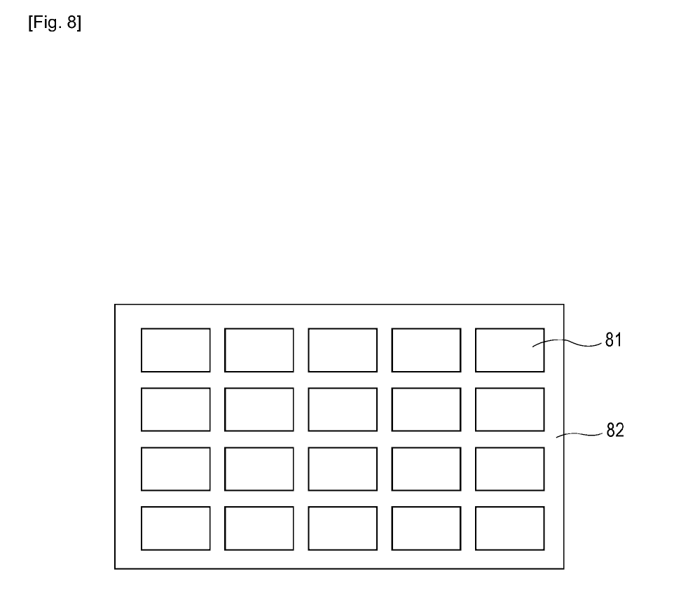

Next, an acrylic resin (PC415 manufactured by JSR Corporation) was applied onto the substrate 10 and the lower electrode 12 to form a film by spin-coating. In the spin-coating, the number of revolutions was set to 1,200 rpm. Next, the resulting acrylic resin film was pre-baked and then exposed to light having an illumination intensity of 100 mW/cm² with a photomask 82 illustrated in FIG. 8 and having openings 81 at positions at which organic electroluminescent elements corresponding to respective sub-pixels were to be formed. Next, the acrylic resin film was developed with a developer (NMD-3 manufactured by Tokyo Ohka Kogyo Co., Ltd.) and then post-baked at 200 degrees Celsius to form a bank 25 in an area other than the areas where the organic electroluminescent elements were to be provided. Here, the thickness of the bank 25 was 1.5 micrometers. The edges of the bank 25 were disposed on the lower electrode 12 and had a tapered shape of about 40 degrees. The area on which the lower electrode was exposed had a rectangular shape having a length of 75 micrometers and a width of 8 micrometers, and the distance between adjacent exposed regions in the horizontal direction was 24 micrometers. Note that, considering the alignment accuracy in the photolithographic technique for forming the pattern of the lower electrode and the like, the distance between adjacent exposed regions in the horizontal direction can be controlled to be plus/minus 5 micrometers or less. On the other hand, the reason why the distance between adjacent exposed regions in the horizontal direction was set to 24 micrometers in this example is that the alignment accuracy (plus/minus about 12 micrometers) of the metal mask was taken into consideration.

### STEP OF FORMING ORGANIC ELECTROLUMINESCENT LAYER (EXAMPLE 1)

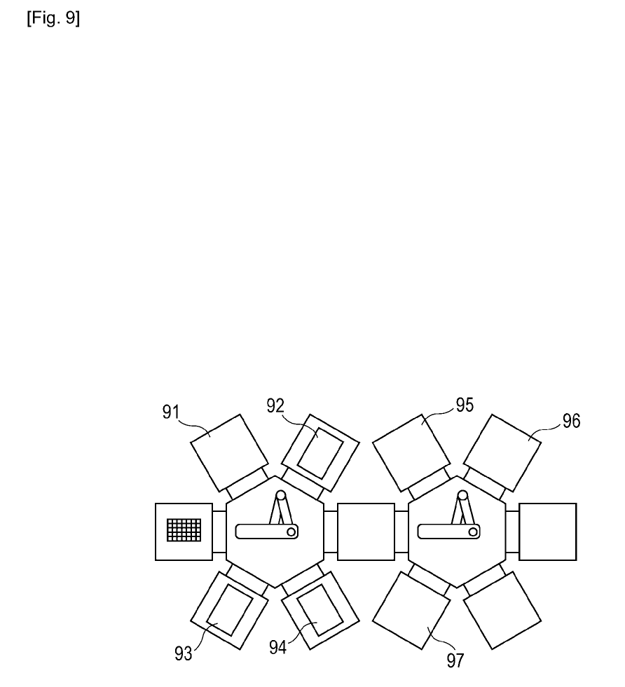

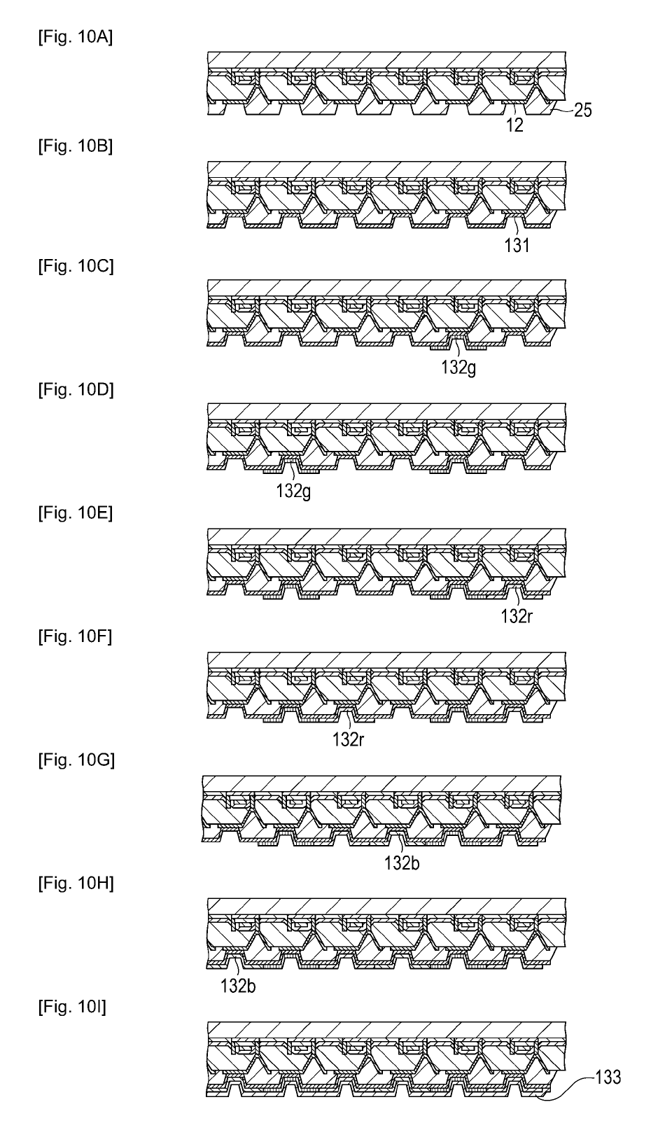

Next, an organic electroluminescent layer was formed by a method described below. FIG. 9 is a schematic view of an apparatus for forming an organic electroluminescent layer. FIGS. 10A to 10J are schematic cross-sectional views showing a process of forming the organic electroluminescent layer and the upper electrode.

First, the substrate 10 obtained after the formation of the bank 25 was placed in the apparatus so that a surface of the substrate 10, the surface to be processed, (i.e., surface on which the lower electrode 12, the bank 25, and the like were provided) was directed in the downward direction, and the apparatus was then evacuated. Next, a dehydration process of the substrate 10 was sufficiently performed by heating the substrate 10. FIG. 10A shows the cross-sectional structure of the substrate 10 in this state.

Next, the substrate 10 was conveyed to a first deposition chamber 91, and alpha-NPD was deposited on the bank 25 and the lower electrode 12 to form a hole-transporting layer 131 (FIG. 10B). In the deposition of the hole-transporting layer 131, a mask 82 having openings 81 at positions corresponding to display areas shown in FIG. 8 was used, and the hole-transporting layer 131 was deposited as a layer common in each display area. In the deposition of the hole-transporting layer 131, a molybdenum crucible was used for an evaporation source, and vapor deposition was conducted by heating the crucible with a sheath heater surrounding the crucible in a spiral manner.

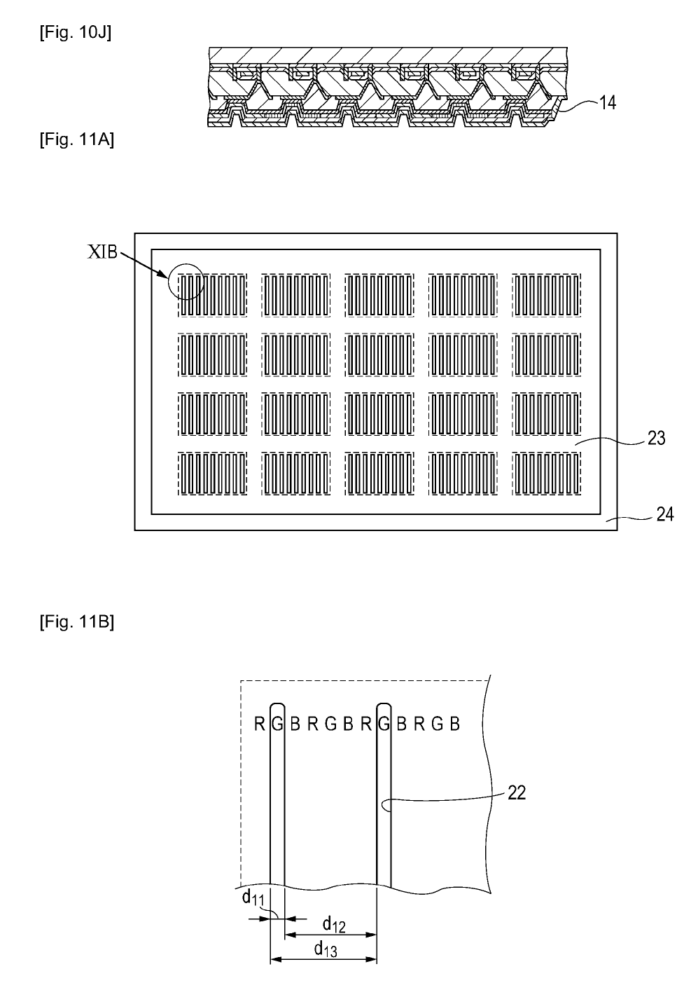

Next, the substrate 10 obtained after the formation of the hole-transporting layer 131 was moved to a second deposition chamber 92, and a green (G) luminescent layer 132g was formed on the hole-transporting layer 131 by a vacuum deposition method. FIG. 11A is an overall schematic view of a mask 23 used in forming the G luminescent layer 132g, and FIG. 11B is a partially enlarged schematic view of portion XIB in FIG. 11A. The material of the mask 23 was Invar. An opening 22 of the mask 23 had a length of 46.2 mm, a width (d₁₁) of 32 micrometers, a distance (d₁₂) between adjacent openings of 160 micrometers, and a repetition pitch (d₁₃(=d₁₁+d₁₂)) of 192 micrometers. The mask 23 included a frame 24 composed of Invar and having a width and a thickness of 20 mm. A foil having a thickness of 30 micrometers was provided at the periphery of the openings 22. This foil was formed by an etching method and welded to the mask while applying a tension that could substantially cancel the elongation due to thermal expansion.

In forming the G luminescent layer 132g, first, the mask 23 was placed so that the positions of the openings 22 of the mask 23 were aligned with the positions of the areas corresponding to G sub-pixels 11g located at the (2n-1)th positions numbered from the left end of each display area. Next, materials for the G luminescent layer 132g, the materials being generated from evaporation sources, were deposited to form the G luminescent layer 132g on the hole-transporting layer 131 (FIG. 10C). The G luminescent layer 132g was formed by respectively charging Alq₃ serving as a host and coumarin 6 serving as a guest (luminous compound) in two evaporation sources, and codepositing these compounds so that the weight ratio of Alq₃:coumarin 6 was 99:1. In forming the G luminescent layer 132g, the film thickness of the layer was controlled while measuring the deposition rate and the film thickness with a quartz-oscillator thickness meter, feeding back the results to the temperature control of the evaporation sources to control the deposition rate, and opening and closing a shutter provided over the evaporation sources.

Next, the position of the mask was changed in the same deposition chamber so that the positions of the openings of the mask were aligned with the positions of the areas corresponding to G sub-pixels 11g located at the (2n)th positions numbered from the left end of each display area. Next, the materials for the G luminescent layer 132g, the materials being generated from the evaporation sources, were deposited to form the G luminescent layer 132g on the hole-transporting layer 131 (FIG. 10D).

Next, the substrate 10 was moved to a fourth deposition chamber 94, and a mask used for forming a red (R) luminescent layer 132r was placed so that the positions of openings of the mask were aligned with the areas corresponding to R sub-pixels 11r located at the (2n-1)th positions numbered from the left end of each display area. Next, materials for the R luminescent layer 132r, the materials being generated from evaporation sources, were deposited to form the R luminescent layer 132r on the hole-transporting layer 131 (FIG. 10E). The R luminescent layer 132r was formed by codepositing Alq₃ serving as a host and [4-(dicyanomethylene)-2-methyl-6(p-dimethylaminostyryl)-4H-pyran] (DCM) serving as a guest so that the weight ratio of Alq₃:DCM was 99:1.

Next, the position of the mask was changed in the same deposition chamber so that the positions of the openings of the mask were aligned with the positions of the areas corresponding to R sub-pixels 11r located at the (2n)th positions numbered from the left end of each display area. Next, the materials for the R luminescent layer 132r, the materials being generated from the evaporation sources, were deposited to form the R luminescent layer 132r on the hole-transporting layer 131 (FIG. 10F).

Next, the substrate 10 was moved to a fifth deposition chamber 95, and a mask used for forming a blue (B) luminescent layer 132b was placed so that the positions of openings of the mask were aligned with the areas corresponding to B sub-pixels 11b located at the (2n-1)th positions numbered from the left end of each display area. Next, materials for the B luminescent layer 132b, the materials being generated from evaporation sources, were deposited to form the B luminescent layer 132b on the hole-transporting layer 131 (FIG. 10G). The B luminescent layer 132b was formed by codepositing a perylene dye and tris[8-hydroxyquinolinato]aluminum (Alq₃) so that the volume ratio of perylene dye:Alq₃ was 1:99.

Next, the position of the mask was changed in the same deposition chamber so that the positions of the openings of the mask were aligned with the positions of the areas corresponding to B sub-pixels 11b located at the (2n)th positions numbered from the left end of each display area. Next, the materials for the G luminescent layer 132b, the materials being generated from the evaporation sources, were deposited to form the B luminescent layer 132b on the hole-transporting layer 131 (FIG. 10H).

Next, the substrate 10 was conveyed to a sixth deposition chamber 96, and lithium fluoride and a phenanthroline compound were codeposited in the sixth deposition chamber 96 using a mask having openings at positions corresponding to the display areas so that the volume ratio of lithium fluoride to the phenanthroline compound was 0.9:99.1. Accordingly, an electron-transporting layer 133 was formed on the respective luminescent layers 132g, 132r, and 132b (FIG. 10I).

### STEP OF FORMING UPPER ELECTRODE (EXAMPLE 1)

Next, the substrate 10 was conveyed to a seventh deposition chamber 97, and indium zinc oxide (IZO) was deposited in the seventh deposition chamber 97 on the electron-transporting layer 133 by a sputtering method to form an upper electrode 14 (FIG. 10J). In this step, the thickness of the upper electrode 14 was controlled to be 100 nm.

Next, the substrate 10 obtained after the formation of the upper electrode 14 was covered with sealing glass without being exposed to the atmosphere so as to block oxygen, moisture, and the like from the outside, and the substrate 10 was bonded to the sealing glass with an adhesive therebetween. A groove was provided in the sealing glass, and a hygroscopic material composed of zeolite (not shown) was provided in the circumference of a space inside the groove. Next, the base 101 having the twenty organic electroluminescent display apparatuses in total thereon was scribed with a rotary blade to which diamond was fixed to separate the organic electroluminescent display apparatuses from each other.

Lastly, a commercially available polarizer for a display was bonded to the surface of the sealing glass to obtain an organic electroluminescent display apparatus. Connecting terminals (not shown) were connected to an external circuit 15 to drive the organic electroluminescent display apparatus. As a result, a full-color display could be performed on the glass side, the glass having the groove thereon (i.e., upper electrode 14 side).

### EXAMPLE 2

The organic electroluminescent display apparatus shown in FIGS. 4A and 4B was manufactured by the method of the second embodiment. In the description below, the difference from Example 1 will be mainly described.

Pixels included in the organic electroluminescent display apparatus manufactured in Example 2 are constituted by three types of stripe-shaped sub-pixels aligned in the order of RGBG. In this example, a display area includes 480 rows of R sub-pixels 11r and 480 rows of B sub-pixels 11b in the vertical direction, and 320 columns of R sub-pixels 11r and 320 columns of B sub-pixels 11b in the horizontal direction. In contrast, the display area includes 480 rows of G sub-pixels 11b in the vertical direction and 640 columns of G sub-pixels 11b in the horizontal direction. Accordingly, the display area includes 480 pixels in the vertical direction and 320 pixels in the horizontal direction. However, since the G sub-pixels 11g, which have high visibility, are present in 480 rows in the vertical direction and 640 columns in the horizontal direction, an image quality substantially the same as that in Example 1 can be achieved. In this example, one pixel had a length (l₂₁) of 96 micrometers and a width (l₂₂) of 192 micrometers.

### STEP OF FORMING LOWER ELECTRODE (EXAMPLE 2)

A lower electrode 12 and a bank 25 were formed on a substrate 10 by the same methods as those used in Example 1. In this example, the lower electrode 12 on which a G sub-pixel 11g was to be provided had a width of 26 micrometers, and the bank 25 on which a G sub-pixel 11g was to be provided had an opening width of 16 micrometers. On the other hand, the lower electrode 12 on which an R sub-pixel 11r or a B sub-pixel 11b was to be provided had a width of 42 micrometers, and the bank 25 on which an R sub-pixel 11r or a B sub-pixel 11b was to be provided had an opening width of 32 micrometers.

### STEP OF FORMING ORGANIC ELECTROLUMINESCENT LAYER (EXAMPLE 2)

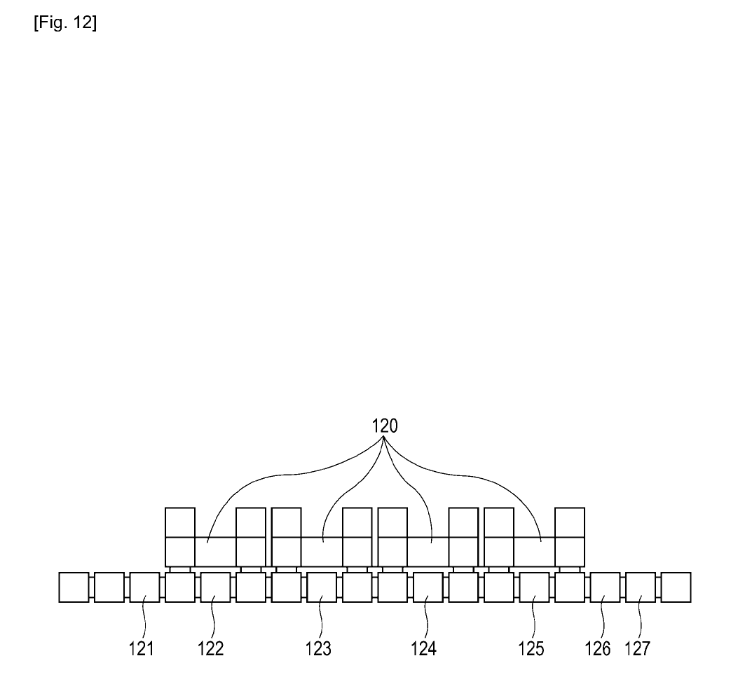

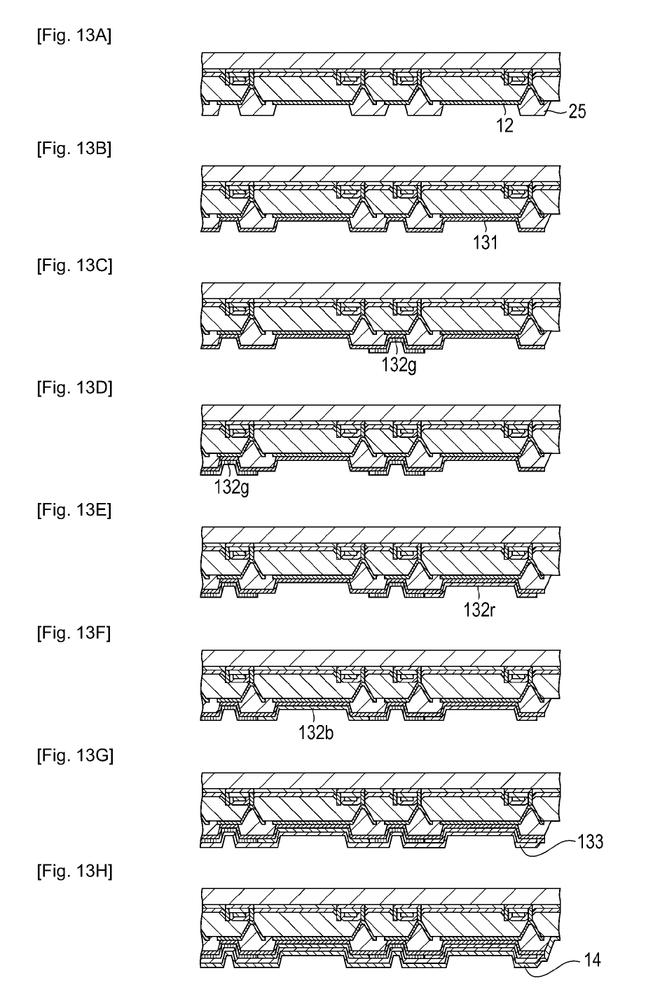

Next, an organic electroluminescent layer 13 and an upper electrode 14 were formed with an in-line apparatus shown in FIG. 12. FIGS. 13A to 13H are schematic cross-sectional views showing a process of forming the organic electroluminescent layer 13 and the upper electrode 14.

First, the substrate 10 obtained after the formation of the bank 25 was placed in the apparatus so that a surface of the substrate 10, the surface to be processed, (i.e., surface on which the lower electrode 12, the bank 25, and the like were provided) was directed in the downward direction, and the apparatus was then evacuated. Next, a dehydration process of the substrate 10 was sufficiently performed by heating the substrate 10. FIG. 13A shows the cross-sectional structure of the substrate 10 in this state.

Next, the substrate 10 was conveyed to a first deposition chamber 121, and alpha-NPD was deposited on the bank 25 and the lower electrode 12 to form a hole-transporting layer 131 (FIG. 13B). In the deposition of the hole-transporting layer 131, as shown in FIG. 8, a mask 82 having openings 81 at positions corresponding to display areas was used, and the hole-transporting layer 131 was deposited as a layer common in each display area. In the deposition of the hole-transporting layer 131, a rectangular parallelepiped box-shaped molybdenum crucible composed of molybdenum was used for an evaporation source, and vapor deposition was conducted by heating the side faces of the crucible with a sheath heater.

Next, the substrate obtained after the formation of the hole-transporting layer 131 was conveyed to a second deposition chamber 122, and a G luminescent layer 132g was formed in areas where G sub-pixels 11g are to be provided. In this step, as in Example 1, a G luminescent layer 132g corresponding to G sub-pixels 11g located at the (2n-1)th positions numbered from the left end of each display area was selectively formed (FIG. 13C). Next, the substrate 10 was conveyed to a third deposition chamber 123, and a G luminescent layer 132g corresponding to G sub-pixels 11g located at the (2n)th positions numbered from the left end of each display area was selectively formed (FIG. 13D). Note that when the G luminescent layer 132g is formed with the apparatus shown in FIG. 12, the mask used can be adequately detached and then returned to the previous position through a mask conveying path 120 provided in parallel. Therefore, a single mask can be used a plurality of times.

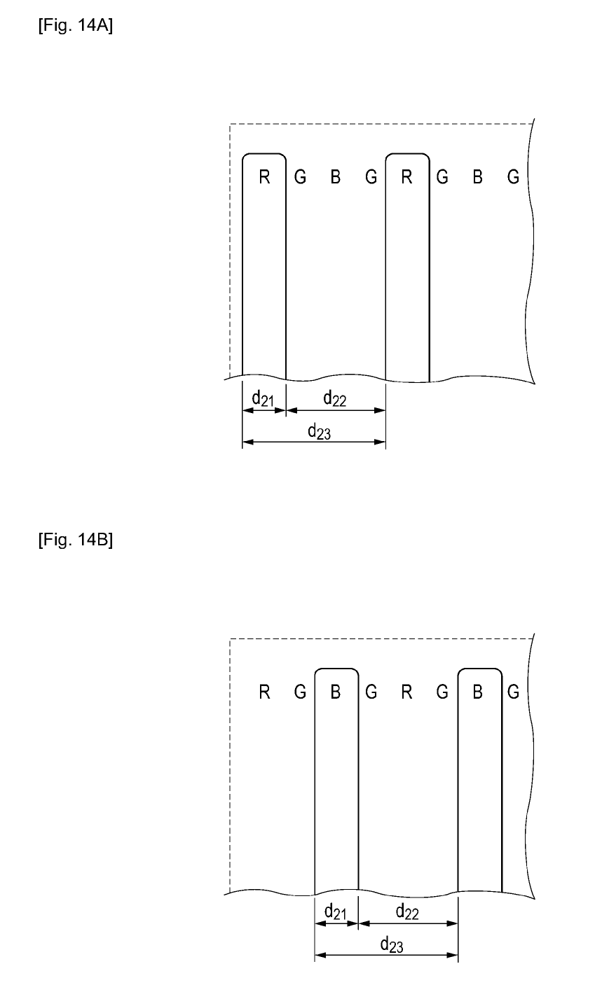

Next, the substrate 10 was conveyed to a fourth deposition chamber 124, and a mask used for forming an R luminescent layer 132r was aligned at a predetermined position. FIG. 14A is a schematic view of a mask used in a step of forming the R luminescent layer 132r in Example 2. The mask used had a length of an opening of 46.2 mm, a width (d₂₁) of 56 micrometers, a distance (d₂₂) between adjacent openings of 136 micrometers, and a repetition pitch (d₂₃(=d₂₁+d₂₂)) of 192 micrometers. When the R luminescent layer 132r was formed, box-shaped crucibles in which the host and guest used in Example 1 were respectively placed were prepared, and codeposition of these host and guest compounds was conducted.

Next, the substrate 10 was conveyed to a fifth deposition chamber 125, and a mask used for forming a B luminescent layer 132b was aligned at a predetermined position. FIG. 14B is a schematic view of a mask used in a step of forming the B luminescent layer 132b in Example 2. The mask used had the same dimensions of the length of an opening, the width, the distance between adjacent openings, and the repetition pitch as those of the mask used for forming the R luminescent layer 132r.

Next, the substrate 10 was conveyed to a sixth deposition chamber 126. Next, lithium fluoride and a phenanthroline compound were codeposited in the sixth deposition chamber 126 using, as shown in FIG. 8, the mask 82 having openings 81 at positions corresponding to the display areas so that the volume ratio of lithium fluoride to the phenanthroline compound was 0.9:99.1. Accordingly, an electron-transporting layer 133 was formed on the respective luminescent layers 132g, 132r, and 132b (FIG. 13G).

### STEP OF FORMING UPPER ELECTRODE (EXAMPLE 2)

Next, the substrate 10 was conveyed to a seventh deposition chamber 127, and IZO was deposited in the seventh deposition chamber 127 on the electron-transporting layer 133 by a sputtering method to form an upper electrode 14 (FIG. 13H). In this step, the thickness of the upper electrode 14 was controlled to be 100 nm.

Next, the substrate 10 obtained after the formation of the upper electrode 14 was covered with sealing glass without being exposed to the atmosphere so as to block oxygen, moisture, and the like from the outside, and the substrate 10 was bonded to the sealing glass with an adhesive therebetween. A groove was provided in the sealing glass, and a hygroscopic material composed of zeolite (not shown) was provided in the circumference of a space inside the groove. Next, the base having the twenty organic electroluminescent display apparatuses in total thereon was scribed with a rotary blade to which diamond was fixed to separate the organic electroluminescent display apparatuses from each other.

Lastly, a commercially available polarizer for a display was bonded to the surface of the sealing glass to obtain an organic electroluminescent display apparatus. Connecting terminals (not shown) were connected to an external circuit 15 to drive the organic electroluminescent display apparatus. As a result, a full-color display could be performed on the glass side, the glass having the groove thereon (i.e., upper electrode 14 side).

### EXAMPLE 3

The organic electroluminescent display apparatus shown in FIGS. 6A and 6B was manufactured by the method of the third embodiment. In the description below, the difference from Example 1 and Example 2 will be mainly described.

Pixels included in the organic electroluminescent display apparatus manufactured in Example 3 are constituted by three types of stripe-shaped sub-pixels aligned in the order of RGB or BGR. In this example, a display area includes 480 rows of respective types of sub-pixels in the vertical direction, and 640 columns of respective types of sub-pixels in the horizontal direction. In this example, the shape of each pixel was a square having a side (l₃₁) of 96 micrometers, and an organic electroluminescent element corresponding to one sub-pixel was provided in an area of 96 micrometers in the vertical direction and 32 micrometers in the horizontal direction.

### STEP OF FORMING LOWER ELECTRODE (EXAMPLE 3)

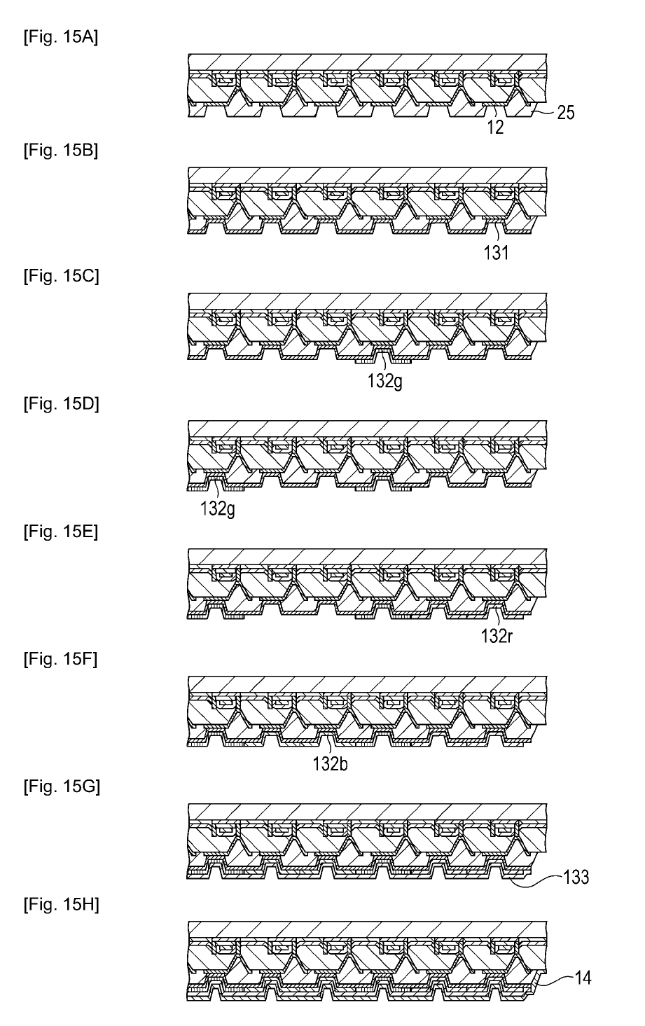

A lower electrode 12 and a bank 25 were formed on a substrate 10 by the same methods as those used in Example 1 (FIG. 15A). In this example, the lower electrode 12 on which a G sub-pixel 11g or a B sub-pixel 11b was to be provided had a width of 21 micrometers, and the bank 25 on which a G sub-pixel 11g or a B sub-pixel 11b was to be provided had an opening width of 11 micrometers. On the other hand, the lower electrode 12 on which an R sub-pixel 11r was to be provided had a width of 20 micrometers, and the bank 25 on which an R sub-pixel 11r was to be provided had an opening width of 10 micrometers.

### STEP OF FORMING ORGANIC ELECTROLUMINESCENT LAYER (EXAMPLE 3)

An organic electroluminescent layer including a luminescent layer corresponding to the respective types of sub-pixels was formed by the same methods as those used in Example 2 (FIGS. 15B to 15G). In Example 3, as shown in FIG. 6A, the alignment pattern of sub-pixels is RRGBBGR from the left end of the display area, and specifically, two R columns (RR) are disposed at the end. This is because openings of a mask used for forming the R luminescent layer have a width corresponding to two sub-pixels. Here, R sub-pixels located at the leftmost column are dummy sub-pixels. However, if the mask used has a narrow opening width exceptionally at the left end of the display area, the R sub-pixels located at the leftmost column in the display area can have a width corresponding to one sub-pixel.

### STEP OF FORMING UPPER ELECTRODE (EXAMPLE 3)

An upper electrode 14 was formed on the organic electroluminescent layer 13 by the same method as that used in Example 2 (FIG. 15H).

Next, sealing of the organic electroluminescent elements and processing of the substrate were conducted as in Example 2 to obtain organic electroluminescent display apparatuses.

Lastly, a commercially available polarizer for a display was bonded to the surface of sealing glass to obtain an organic electroluminescent display apparatus. Connecting terminals (not shown) were connected to an external circuit 15 to drive the organic electroluminescent display apparatuses. As a result, a full-color display could be performed on the glass side, the glass having a groove thereon (i.e., upper electrode 14 side).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-122128, filed May 20, 2009, which is hereby incorporated by reference herein in its entirety.

### REFERENCE SIGNS LIST

1, 4, 6 Organic electroluminescent display apparatus

10 Substrate

11 Pixel

11g G sub-pixel

11r R sub-pixel

11b B sub-pixel

1. A method for manufacturing an organic electroluminescent display apparatus that includes a substrate and a plurality of pixels each including two or more types of sub-pixels, the pixels being arranged in a display area of the substrate, and, among the sub-pixels, one type of sub-pixels being specified sub-pixels that are provided at certain intervals, the method comprising the steps of:
in forming the specified sub-pixels,
(i) selectively forming the (2n-1)th specified sub-pixels (wherein n represents an integer of 1 or more) numbered from a side end of the display area using a mask having openings at positions corresponding to the (2n-1)th specified sub-pixels numbered from the side end; and
(ii) selectively forming the (2n)th specified sub-pixels (wherein n represents an integer of 1 or more) numbered from the side end using a mask having openings at positions corresponding to the (2n)th specified sub-pixels numbered from the side end.

2. The method according to claim 1, wherein each of the openings of the masks used in steps (i) and (ii) are continuous in the vertical direction.

3. The method according to claim 1, wherein the same evaporation source is used in steps (i) and (ii).

4. The method according to claim 1,
wherein the specified sub-pixels are green (G) sub-pixels,
the sub-pixels are arranged in the order of RGBGRGBG in the horizontal direction, and, after step (ii),
red (R) sub-pixels and blue (B) sub-pixels are sequentially formed by the steps of:
(iii) forming the red sub-pixels; and
(iv) forming the blue sub-pixels.

5. The method according to claim 1,
wherein the sub-pixels are in three colors and include red (R) sub-pixels, green (G) sub-pixels, and blue (B) sub-pixels,
the specified sub-pixels are the green (G) sub-pixels,
pairs of sub-pixels of the same colors are repeatedly disposed with a specified sub-pixel between adjacent pairs, the colors of the pairs of sub-pixels alternating between red and blue, and
the red (R) sub-pixels and the blue (B) sub-pixels are sequentially formed by the steps of:
(v) forming the red (R) sub-pixels at one time using a mask having openings at positions corresponding to the red (R) sub-pixels; and
(vi) forming the blue (B) sub-pixels at one time using a mask having openings at positions corresponding to the blue (B) sub-pixels.

6. The method according to claim 1, wherein the mask used in step (i) is different from the mask used in step (ii).

7. The method according to claim 1, wherein the pitch of the openings of the masks is 95 micrometers and the width of the openings of the masks is 40 micrometers or less.
